(19) United States
(12) Patent Application Publication
(10) Pub. No.: US 2026/0260610 A1
(43) Pub. Date: Sep. 3, 2026

(54) DISPLAY PANEL, DRIVING METHOD AND DISPLAY DEVICE

(71) Applicant: Wuhan Tianma Micro-Electronics Co., Ltd., Wuhan (CN)

(72) Inventors: Wenshuai ZHANG, Wuhan (CN); Lei WANG, Wuhan (CN)

(21) Appl. No.: 19/236,424

(22) Filed: Jun. 12, 2025

(30) Foreign Application Priority Data
Feb. 28, 2025 (CN) 202510238460.6

(51) Int. Cl. G09G 3/3233; G09G 3/32; G09G 3/3266; G11C 19/28

(52) U.S. Cl. CPC G09G 3/3233; G09G 3/3266; G11C 19/287; G09G 3/32; G09G 2300/0819; G09G 2300/0842; G09G 2310/0286; G09G 2310/04; G09G 2310/08; G09G 2320/045; G09G 2340/0435

(57) ABSTRACT

A display panel includes a gate driving circuit and a plurality of pixel driving circuits, where the gate driving circuit includes N-stage cascaded shift registers, and N≥2. A shift register includes a stage transmission module and at least two gating modules connected to the stage transmission module, where the gating module includes a first gating module and a second gating module. The stage transmission module is configured to output a stage transmission signal. The first gating module and the second gating module are configured to at least receive a frequency control signal, and output a scanning signal through the output ends of the first gating module and the second gating module. In at least some of the shift registers, the output end of the first gating module and the output end of the second gating module are respectively connected to pixel driving circuits of different rows.

### CROSS-REFERENCE TO RELATED DISCLOSURE

This disclosure claims priority of Chinese Patent Disclosure No. 202510238460.6, filed on Feb. 28, 2025, the entire content of which is hereby incorporated by reference.

### FIELD OF THE DISCLOSURE

The present disclosure relates to the field of display technology, and in particular to a display panel, a driving method and a display device.

### BACKGROUND

With the continuous development of science and technology, more and more display products, such as mobile phones, tablets, laptops and smart wearable devices, are widely used in people's daily life and work, bringing great convenience to people's daily life and work, and becoming an indispensable tool for people today.

The normal display of display products is usually controlled by multiple signals. When a special display is required, for example, different areas of a display product in a display frame need to be displayed at different refresh rates, display abnormalities are likely to occur. Therefore, how to improve the display accuracy of display products has become one of the technical issues that need to be solved urgently at this stage.

### SUMMARY

In order to solve the above technical problems, the present disclosure provides a display panel and a driving method thereof, and a display device, aiming to improve the display accuracy of display products.

In a first aspect, the present disclosure provides a display panel, including a gate driving circuit and a plurality of pixel driving circuits, where the gate driving circuit includes N-stage cascaded shift registers, and N≥2, where: a shift register includes a stage transmission module and at least two gating modules connected to the stage transmission module, and the at least two gating modules include a first gating module and a second gating module; the stage transmission module is configured to output a stage transmission signal, and a stage transmission signal of an i-th stage shift register is an input signal of a j-th stage shift register, where 1≤i≤N, 1≤j≤N, and i≠j; and the first gating module and the second gating module are configured to at least receive a frequency control signal and output a scanning signal through an output end of the first gating module and an output end of the second gating module, and in at least some of the shift registers, the output end of the first gating module and the output end of the second gating module are respectively connected to pixel driving circuits of different rows.

In a second aspect, based on similar inventive concepts, the present disclosure provides a driving method for driving a display panel disclosed elsewhere. The first gating module receives a first frequency control signal, and the second gating module receives a second frequency control signal. The driving method includes controlling the first frequency control signal and the second frequency control signal to maintain a same potential in at least one display frame, and the first frequency control signal and the second frequency control signal are controlled to undergo a potential leap in at least one display frame. A display frame includes a first stage and a second stage. In the first stage, the first frequency control signal and the second frequency control signal maintain the same potential. In the second stage, the first frequency control signal and the second frequency control signal undergo a potential leap, and the potential leap timing of the first frequency control signal is earlier than the potential leap timing of the second frequency control signal.

In a third aspect, based on similar inventive concepts, the present disclosure provides a display device, including the display panel disclosed elsewhere.

It should be understood that the content described in this section is not intended to identify the key or important features of the embodiments of the present disclosure, nor are they intended to limit the scope of the present disclosure. Other aspects of the present disclosure may be understood by those skilled in the art in light of the detailed description, the claims, and the drawings of the present disclosure.

### BRIEF DESCRIPTION OF THE DRAWINGS

In order to better understand the technical solution of the present disclosure, the embodiments of the present disclosure are described in details hereinafter with reference to the accompanying drawings.

In order to more thoroughly illustrate the technical solutions of the embodiments of the present disclosure, the drawings essential for understanding the embodiments will be briefly introduced hereinafter. Apparently, the drawings described below are merely some embodiments of the present disclosure. For a person skilled in the art, other drawings can be obtained based on these drawings without making creative efforts.

FIG. 1 is a schematic structural diagram of a display panel in accordance with an embodiment of the present disclosure;

FIG. 2 is a schematic structural diagram of a gate driving circuit in a display panel in accordance with an embodiment of the present disclosure;

FIG. 3 is a connection schematic diagram between a shift register and a pixel driving circuit in a gate driving circuit;

FIG. 4 is a planar schematic structural diagram of a display panel in accordance with an embodiment of the present disclosure;

FIG. 5 is a connection schematic diagram between a shift register and a pixel driving circuit in a gate driving circuit corresponding to FIG. 4;

FIG. 6 is a circuit diagram of a pixel driving circuit in accordance with an embodiment of the present disclosure;

FIG. 7 is another circuit diagram of a pixel driving circuit in accordance with an embodiment of the present disclosure;

FIG. 8 is a sequence diagram of the pixel driving circuit in FIG. 6;

FIG. 9 is a connection schematic diagram between a gate driving circuit and a pixel driving circuit in the related technologies;

FIG. 10 is another connection schematic diagram between a shift register and a pixel driving circuit in a gate driving circuit;

FIG. 11 is another connection schematic diagram between a shift register and a pixel driving circuit in a gate driving circuit;

FIG. 12 is a schematic structural diagram of a gate driving circuit in accordance with an embodiment of the present disclosure;

FIG. 13 is another schematic structural diagram of a gate driving circuit in accordance with an embodiment of the present disclosure;

FIG. 14 is a driving sequence diagram of the stage transmission module of the shift register in FIG. 13;

FIG. 15 is a schematic structural diagram of a first gating module and a second gating module in accordance with an embodiment of the present disclosure;

FIG. 16 is a working sequence diagram of the gating module in FIG. 15;

FIG. 17 is another working sequence diagram of the gating module in FIG. 15;

FIG. 18 is a driving sequence diagram of a pixel driving circuit by a gate driving circuit in accordance with an embodiment of the present disclosure;

FIG. 19 is another schematic structural diagram of a gate driving circuit in accordance with an embodiment of the present disclosure;

FIG. 20 is a schematic structural diagram of a gating module corresponding to the embodiment of FIG. 19;

FIG. 21 is a flow chart of a driving method for driving a display panel in accordance with an embodiment of the present disclosure; and

FIG. 22 is a schematic structural diagram of a display device in accordance with an embodiment of the present disclosure.

### DETAILED DESCRIPTION

In order to more clearly understand the objectives, features and advantages of the present disclosure, the scheme of the present disclosure will be further described below. It should be noted that the embodiments of the present disclosure and the features in the embodiments can be combined with each other without conflict.

In the following description, many specific details are set forth to facilitate a full understanding of the present disclosure, but the present disclosure may also be implemented in other ways different from those described herein. Obviously, the embodiments in the description are merely part of the embodiments of the present disclosure, rather than all of the embodiments.

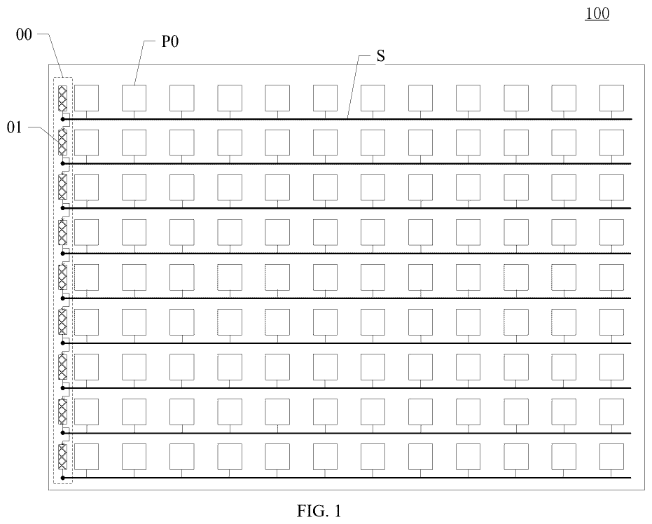

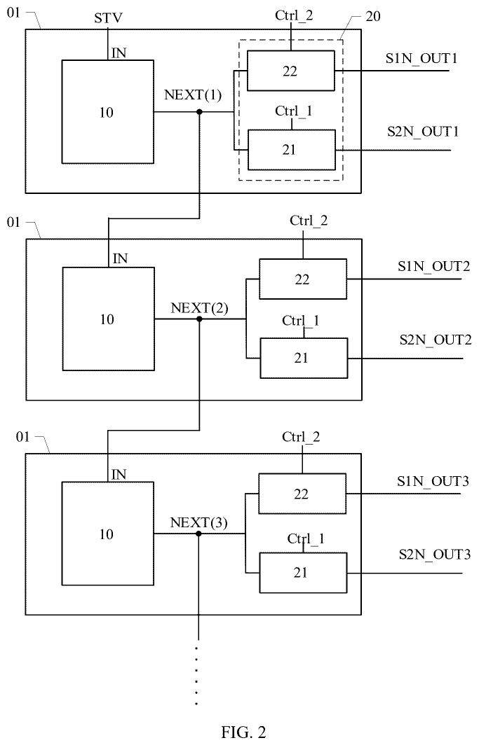

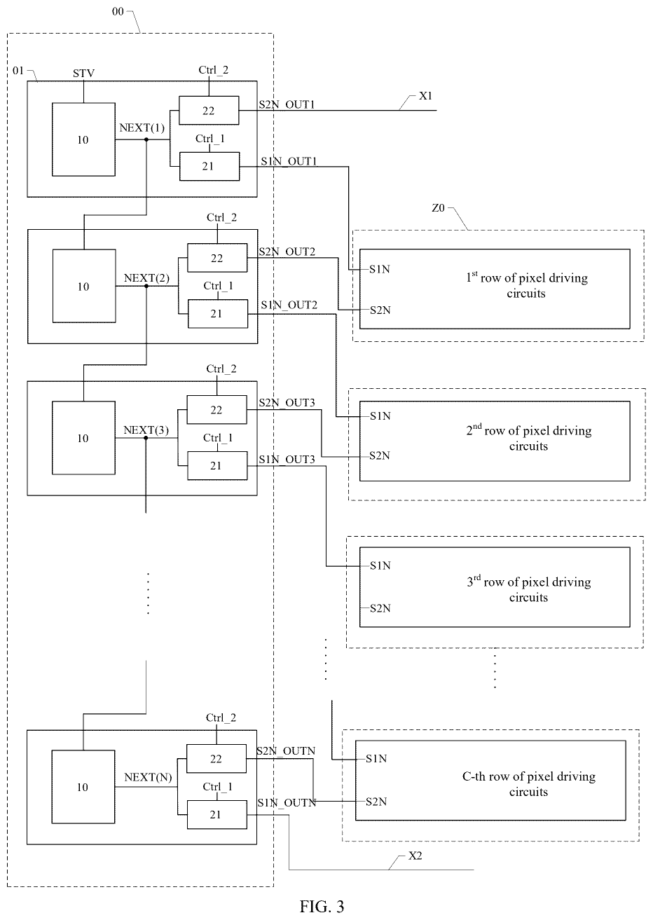

FIG. 1 illustrates a schematic structural diagram of a display panel 100 in accordance with an embodiment of the present disclosure. FIG. 2 illustrates a schematic structural diagram of a gate driving circuit 00 in the display panel 100 in accordance with an embodiment of the present disclosure. FIG. 3 illustrates a connection schematic diagram between a shift register 01 and a pixel driving circuit P0 in the gate driving circuit 00.

Referring to FIGS. 1 to 3, the embodiments of the present disclosure provide a display panel 100, including a gate driving circuit 00 and a plurality of pixel driving circuits P0. The gate driving circuit 00 includes N-stage cascaded shift registers 01, where N≥2. A shift register 01 includes a stage transmission module 10 and at least two gating modules 20 connected to the stage transmission module 10. The gating module 20 includes a first gating module 21 and a second gating module 22. The stage transmission module 10 is configured to output a stage transmission signal NEXT, and the stage transmission signal of the i-th stage shift register is the input signal of the j-th stage shift register, 1≤i≤N, 1≤j≤N, and i≠j.

The first gating module 21 and the second gating module 22 are configured to at least receive a frequency control signal Ctrl, and output a scanning signal S1N_OUT/S2N_OUT through the output end of the first gating module 21 and the second gating module 22. In at least part of the shift register 01, the output end of the first gating module 21 and the output end of the second gating module 22 are respectively connected to the pixel driving circuits P0 of different rows.

It should be noted that FIG. 1 merely illustrates a display panel with a rectangular structure as an example, and does not limit the actual shape of the display panel. In some embodiments of the present disclosure, the display panel may also be embodied in any other feasible shape such as a circle, a rounded rectangle, etc.

Optionally, the display panel provided in the disclosed embodiments may be an organic light emitting display panel, and the corresponding light emitting element is an organic light emitting element. Apparently, in some embodiments of the present disclosure, the display panel may also use a display panel using inorganic light emitting diode display technology, such as a Micro LED display panel, a Mini LED display panel, etc., which is not limited in the present disclosure.

In order to clearly illustrate the relative position relationship between the gate driving circuit and the pixel driving circuits, other structures of the display panel such as the light emitting elements are not shown in FIG. 1. The pixel driving circuits are only exemplified in a rectangular structure, and the number and arrangement of the pixel driving circuits are not limited thereto. Additionally, the position of the gate driving circuit in the display area in FIG. 1 is only schematic, and it is only illustrated by introducing a group of gate driving circuit 00 into the display panel, and setting the gate driving circuit 00 in the non-display area on one side of the display area, but the present disclosure is not limited thereto.

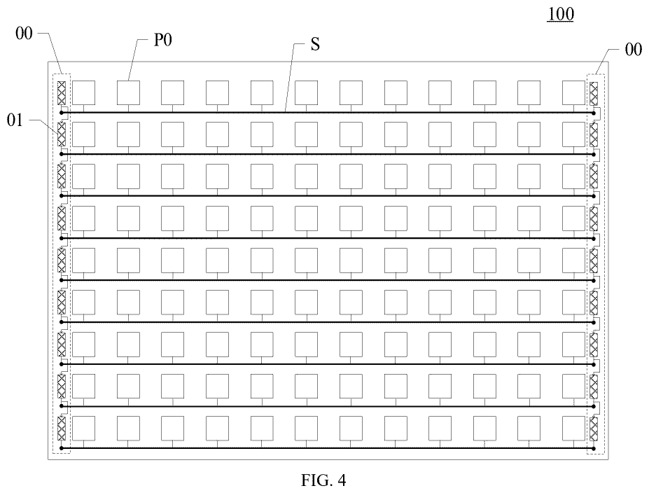

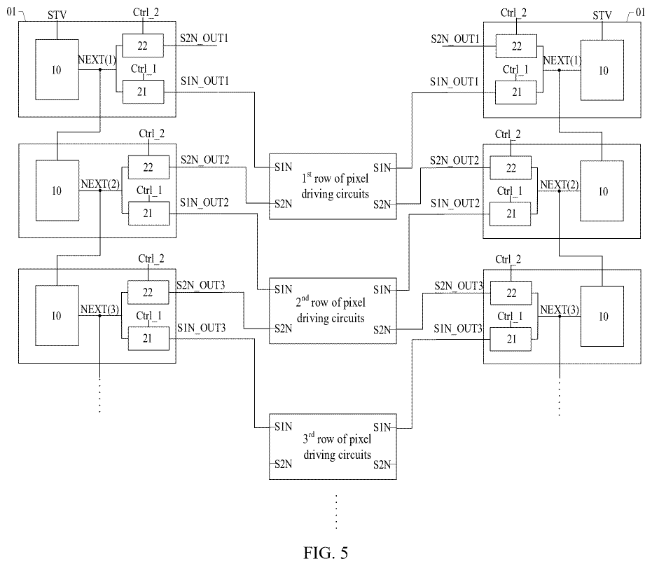

In some embodiments of the present disclosure, two groups of gate driving circuits may be arranged in the display panel. For example, referring to FIGS. 4 and 5, FIG. 4 illustrates another planar schematic structural diagram of the display panel in accordance with the present disclosure, and FIG. 5 illustrates a connection schematic diagram of the shift register and the pixel driving circuit in the gate driving circuit corresponding to FIG. 4. In the illustrated embodiment, two groups of gate driving circuits 00 are introduced into the display panel, and the two groups of gate driving circuits 00 are respectively arranged in the left and right border areas of the display panel. The mode of driving the pixel driving circuits P0 by two groups of gate driving circuits 00 is conducive to improving the transmission efficiency and transmission reliability of the scanning signal.

Optionally, referring to FIGS. 1 to 5, the gate driving circuit 00 includes a plurality of cascaded shift registers 01. The output end of a shift register 01 is connected to a scan line S, the scan line S is further electrically connected to pixel driving circuits P0, and the shift register 01 provides a scanning signal to the pixel driving circuits P0 through the scan line S. The scanning signal includes, for example, a reset control signal, a data writing control signal, a light emitting control signal, etc., to control the operation of the pixel driving circuit P0. Optionally, at least two different control signals correspond to different gate driving circuits, for example, the gate driving circuit that sends the reset control signal and the gate driving circuit that sends the light emitting control signal are two independent gate driving circuits.

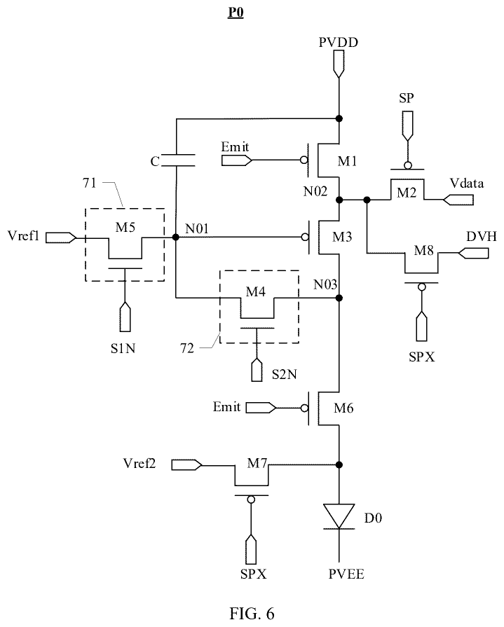

FIG. 6 illustrates a circuit diagram of a pixel driving circuit in accordance with an embodiment of the present disclosure. Taking FIG. 6 as an example, the pixel driving circuit P0 includes a first transistor M1, a second transistor M2, a third transistor M3, a fourth transistor M4, a fifth transistor M5, a sixth transistor M6, a seventh transistor M7, an eighth transistor M8 and a capacitor C, where the third transistor M3 is a driving transistor, which is used to provide a driving current for the light emitting element D0. The gate, the first electrode and the second electrode of the driving transistor are respectively connected to the first sub-node N01, the third sub-node N03 and the second sub-node N02. The first electrode and the second electrode of the fifth transistor M5 are respectively connected to the first reset signal terminal Vref1 and the first sub-node N01. The gate of the fifth transistor M5 is connected to the first control signal terminal S1N, and is used to receive the reset control signal. The fifth transistor M5 is used to provide the first reset signal Vref1 to the first sub-node N01. The first electrode and the second electrode of the second transistor M2 are respectively connected to the data voltage signal terminal Vdata and the second sub-node N02, the gate receives the control signal SP, and the second transistor M2 is used to transmit the data voltage signal Vdata to the second sub-node N02. It should be noted that the signal terminals and the signals transmitted by the signal terminals in the embodiments of the present disclosure are represented by the same reference numerals. The first electrode and the second electrode of the fourth transistor M4 are respectively connected to the third sub-node N03 and the first sub-node N01, and the gate is connected to the second control signal terminal S2N for receiving the control signal S2N. The fourth transistor M4 is used to perform threshold compensation on the third transistor M3. The first electrode and the second electrode of the seventh transistor M7 are respectively connected to the second reset signal terminal Vref2 and the first electrode of the light emitting element D0, and the gate is connected to the control signal terminal SPX. The seventh transistor M7 is used to reset the first electrode of the light emitting element D0. The first electrode and the second electrode of the eighth transistor M8 are respectively connected to the bias adjustment signal terminal DVH and the second sub-node N02, and the gate is connected to the control signal terminal SPX. The first electrode and the second electrode of the first transistor M1 are respectively connected to the first power signal terminal PVDD and the second sub-node N02, and the gate is connected to the light control signal terminal Emit. The first electrode and the second electrode of the sixth transistor M6 are respectively connected to the third sub-node N03 and the first electrode of the light emitting element D0, and the gate is connected to the light control signal terminal Emit, which is used to transmit the driving current to the light emitting element D0. The second electrode of the light emitting element D0 is connected to the second power supply signal PVEE.

It should be noted that the embodiments of the present disclosure are merely described by taking the gates of the seventh transistor M7 and the eighth transistor M8 connected to the control signal terminal SPX as an example, but the present disclosure is not limited thereto. It should also be noted that the pixel driving circuit in FIG. 6 is merely for schematic purposes, and the present disclosure does not limit the specific structure of the pixel driving circuit.

In the illustrated embodiment in FIG. 6, the fourth transistor M4 and the fifth transistor M5 connected to the first sub-node N01 are N-type transistors, and the N-type transistors can be oxide transistors. The signal for controlling the conduction of the fourth transistor M4 and the fifth transistor M5 is a high-level signal, and the other transistors are all P-type transistors. In this embodiment, the fourth transistor M4 and the fifth transistor M5 are N-type transistors. When the N-type transistors are oxide transistors, it is beneficial to reducing the leakage of the fourth transistor M4 and the fifth transistor M5 to the first sub-node N01, thereby facilitating the stability of the potential of the gate of the driving transistor connected to the first sub-node N01.

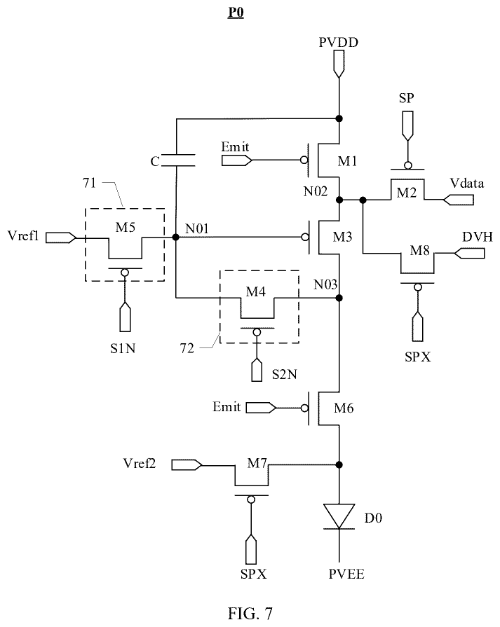

In some embodiments, the pixel driving circuit may also be embodied as other structures. For example, FIG. 7 illustrates another circuit schematic diagram of a pixel driving circuit in accordance with an embodiment of the present disclosure. The connection relationship and working principle are the same as those in FIG. 6. The only difference from FIG. 6 is that the fourth transistor M4 and the fifth transistor M5 are P-type transistors, and the P-type transistors are turned on under the control of a low-level signal. When all the transistors in the embodiment shown in FIG. 7 are P-type transistors, it is beneficial to simplify the process of the pixel driving circuit.

In the pixel driving circuits shown in FIGS. 6 and 7, the first control signal terminal S1N, the second control signal terminal S2N, the light emitting control signal terminal Emit, and the control signal terminals SP and SPX are all connected to the gate driving circuits. The first control signal terminal S1N and the second control signal terminal S2N may correspond to the same group of gate driving circuits, and the light emitting control signal terminal Emit, the control signal terminals SP and SPX may correspond to other different gate driving circuits. It should be noted that in the embodiments of the present disclosure, only the structure of the gate driving circuits corresponding to the first control signal terminal S1N and the second control signal terminal S2N are described, and the structure of other gate driving circuits in the display panel is not limited thereto.

The working principle of FIG. 6 will be described below in conjunction with FIG. 8, and the working principle of the pixel driving circuit in FIG. 7 can refer to the description for FIG. 6. FIG. 8 illustrates a sequence diagram of the pixel driving circuit in FIG. 6. In combination with FIGS. 6 and 8, the specific working process of the pixel driving circuit P0 includes an initialization stage t1, a data writing and threshold compensation stage t2, a bias stage t3 and a light emitting stage t4.

In the initialization stage t1, the high-level signal of the first control signal S1N controls the fifth transistor M5 to be turned on, and transmits the first reset signal Vref1 to the control end of the third transistor M3 for initialization, so as to eliminate the residual charge of the previous frame to improve the display effect of the display panel. In the present disclosure, in a part of the time period of the initialization stage t1, the valid levels of the first control signal S1N and the second control signal S2N have an overlapping period, which is conducive to improving the hysteresis problem of the driving transistor during the initialization stage.

In the data writing and threshold compensation stage t2, the fifth transistor M5 is turned off, the control signal SP controls the second transistor M2 to be turned on, the second control signal S2N controls the fourth transistor M4 to be turned on, and the data voltage signal Vdata is written into the third transistor M3 through the second transistor M2. The fourth transistor M4 is connected between the gate and the first electrode of the third transistor M3, and the threshold voltage of the third transistor M3 can be captured to the gate of the third transistor M3, thereby realizing the compensation of the threshold voltage and self-compensating the deviation of the threshold voltage of the driving transistor.

In the bias stage t3, the control signal SPX controls the eighth transistor M8 to be turned on, and the bias adjustment signal DVH is transmitted to the second electrode (i.e., the second sub-node N02) of the driving transistor through the eighth transistor M8 to adjust the bias state of the driving transistor. At the same time, the control signal SPX controls the seventh transistor M7 to be turned on, and the second reset signal Vref2 is transmitted to the anode of the light emitting element D0 through the seventh transistor M7 to reset the light emitting element D0.

In the light emitting stage t4, the second transistor M2, the fourth transistor M4, the fifth transistor M5 and the seventh transistor M7 are all turned off, the first transistor M1, the third transistor M3 and the sixth transistor M6 are all turned on, the driving current is transmitted to the first electrode of the light emitting element D0, and the light emitting element D0 emits light.

It should be noted that the sequence diagram of FIG. 8 is merely for schematic purposes and is not limited thereto. In some embodiments of the present disclosure, pixel driving circuits with different structures may correspond to different sequences.

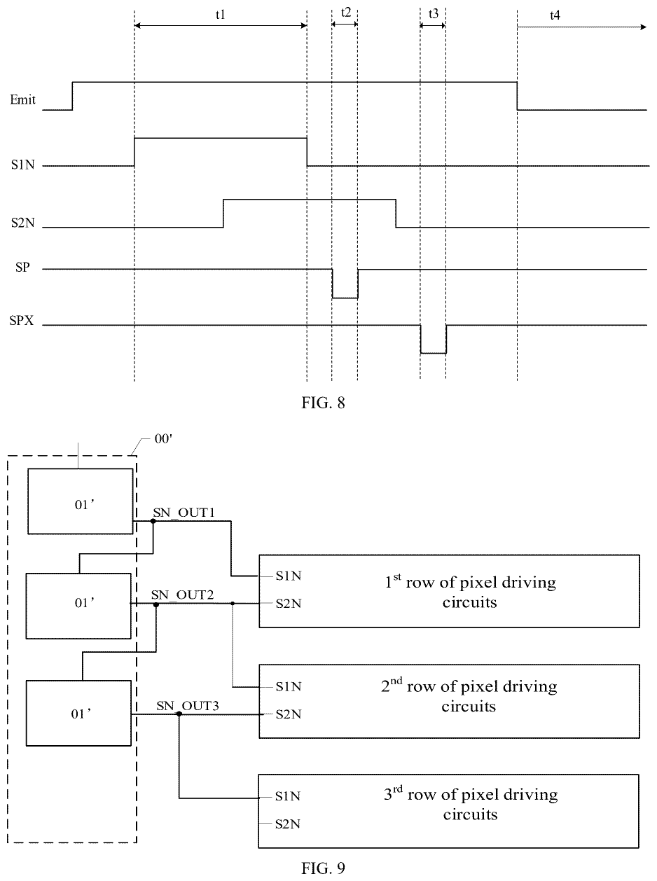

FIG. 9 is a connection diagram of a gate driving circuit 00′ and pixel driving circuits in the related technologies. To simplify the panel design, the shift register for transmitting the reset control signal S1N is usually multiplexed with the shift register for transmitting the control signal S2N, that is, the same shift register is used to transmit the reset control signal S1N and the control signal S2N.

Referring to FIGS. 6 and 9, in the gate driving circuit, the output of the shift register 01′ at this stage can provide the control signal S2N for the pixel driving circuits of the n-th row, and can also provide the reset control signal S1N for the pixel driving circuits of the m-th row. The fourth transistor M4 in the pixel driving circuits of the n-th row is turned on to achieve threshold compensation, and at the same time, the fifth transistor M5 in the pixel driving circuits of the m-th row is controlled to be turned on to achieve resetting of the gate of the driving transistor, where m>n.

For a display panel using such a gate driving circuit, the reset control signal S1N and the control signal S2N corresponding to the two rows of pixel driving circuits are multiplexed. When the display panel needs to implement regional refresh, for example, in two adjacent display areas, the pixel driving circuits in one display area need to be refreshed (the first control signal terminal S1N and the second control signal terminal S2N both need to receive the valid level signal in the scanning signal), while the pixel driving circuits in the other display area do not need to be refreshed (the first control signal terminal S1N and the second control signal terminal S2N both need to receive the invalid level signal in the scanning signal).

Assuming that the pixel driving circuits in the first row need to be refreshed and the pixel driving circuits in the second row do not need to be refreshed, considering that the second-stage shift register 01 is simultaneously connected to the second control signal terminal S2N in the pixel driving circuits of the first row and the first control signal terminal S1N in the pixel driving circuits of the second row, in order to ensure the normal refresh of the pixel driving circuits in the first row, the second-stage shift register needs to output the valid level signal of the control signal S2N. However, in order to ensure that pixel driving circuits are not refreshed in the second row, the corresponding shift register needs to output the invalid level signal of the reset control signal S1N.

It can be seen that the signals required by the pixel driving circuits of the first row and the second row are different, but because the pixel driving circuits of the first row and the second row are connected to the output terminal of the same shift register, the corresponding two control signals are multiplexed, and the output signals are consistent. Thus, they cannot meet the different refresh requirements of the two rows of pixel driving circuits, resulting in display abnormalities when the display panel has a regional refresh requirement.

In order to solve the above problems, the embodiments of the present disclosure improve the structure of the shift register. Referring to FIGS. 2 to 5, among the N stage shift registers included in the gate driving circuit, each shift register includes a stage transmission module 10, and a first gating module 21 and a second gating module 22 connected to the stage transmission module 10. The stage transmission module 10 is configured to transmit a stage transmission signal, and the stage transmission signal of the i-th stage shift register is used as the input signal of the j-th stage shift register.

The first gating module 21 and the second gating module 22 output the scanning signals at least according to the received frequency control signal Ctrl, that is, the same shift register 01 can output two scanning signals through the first gating module 21 and the second gating module 22 respectively. Here, in at least some shift registers, the output end of the first gating module 21 and the output end of the second gating module 22 are respectively connected to the pixel driving circuits of different rows.

Assuming that in a same shift register, the first gating module 21 is connected to the pixel driving circuits of the a-th row, and the second gating module 22 is connected to the pixel driving circuits of the b-th row. When the refresh requirements of different display areas are different, for example, when the pixel driving circuits of the a-th row need to be refreshed, but the pixel driving circuits of the b-th row do not need to be refreshed. The first gating module 21 can output a valid level signal of the scanning signal to the pixel driving circuits of the a-th row to refresh the pixel driving circuits of the a-th row, and the second gating module 22 can output an invalid level signal of the scanning signal to the pixel driving circuits of the b-th row, without refreshing the pixel driving circuits of the b-th row. In this way, the pixel driving circuits with different refresh requirements can all receive the correct scanning signal, which is beneficial to improving the display accuracy of the display panel during regional refresh.

Referring to FIGS. 2 to 5, in some embodiments, in at least one display frame, the first gating module 21 and the second gating module 22 in at least one shift register are configured to receive different frequency control signals respectively. The frequency control signal mentioned in the embodiments of the present disclosure can be regarded as one of the control signals for controlling whether the gating module outputs a valid level signal or not.

For example, when the frequency control signal is a certain level signal, the scanning signal output by the corresponding gating module may include a valid level signal, which can realize the refresh normally of the corresponding row pixel driving circuits. When the frequency control signal is another level signal, the scanning signal output by the corresponding gating module may merely include an invalid level signal, and the pixel driving circuits of the corresponding row are not refreshed.

Therefore, in at least one display frame, if the first gating module 21 and the second gating module 22 in the shift register receive different frequency control signals, different refresh requirements of the pixel driving circuits of different rows connected to the first gating module 21 and the second gating module 22 in the shift register can be achieved, to meet the regional refresh requirements of the display panel. It is also beneficial to ensure that the pixel driving circuits with different refresh requirements can all receive the correct scanning signals, and to improve the display accuracy during regional refresh. The following embodiments will further illustrate the differences in frequency control signals in conjunction with sequences.

Referring to FIGS. 2 and 3, in some embodiments, the first gating module 21 and the second gating module 22 are configured to receive different frequency control signals respectively. Specifically, in at least one display frame and at least one shift register, one of the frequency control signals received by the first gating module 21 and the second gating module 22 is a high-level signal, and the other is a low-level signal. For example, the first gating module 21 receives the first frequency control signal Ctrl_1, and the second gating module 22 receives the second frequency control signal Ctrl_2. In this specific shift register, the potentials of the first frequency control signal Ctrl_1 and the second frequency control signal Ctrl_2 are opposite.

Optionally, when the frequency control signal received by a gating module is a low-level signal, the scanning signal output by the gating module may include a valid level signal to achieve refreshing of the pixel driving circuits. When the frequency control signal received by a gating module is a high-level signal, the scanning signal output by the gating module does not include a valid level signal, and the pixel driving circuits are not refreshed.

Apparently, in some embodiments of the present disclosure, when the frequency control signal received by a gating module is high, the scanning signal output by the gating module can be controlled not to include a valid level signal, and vice versa, when the received frequency control signal is low, the scanning signal output by the gating module can be controlled to include a valid level signal, and the present disclosure is not limited thereto. By controlling the output of the gating module by setting the frequency control signal high or low, and different refresh requirements in different areas may be achieved, which is beneficial to simplify the signal control of a display panel.

Referring to FIGS. 2 and 3, in some embodiments, in at least one display frame, in at least one shift register, the scanning signal transmitted by the first gating module 21 to the corresponding pixel driving circuit includes a valid level signal, at this time, the pixel driving circuit connected to the first gating module 21 can be refreshed normally. The scanning signal output by the second gating module 22 to the corresponding pixel driving circuit does not include a valid level signal, at this time, the pixel driving circuit connected to the first gating module 21 does not need to be refreshed.

The above embodiment is described by merely taking the example that the pixel driving circuits connected to the first gating module 21 are refreshed normally, and the pixel driving circuits connected to the second gating module 22 do not need to be refreshed. In some embodiments of the present disclosure, the output signals of the first gating module 21 and the second gating module 22 can be controlled to ensure that the pixel driving circuits connected to the first gating module 21 are not refreshed, and the pixel driving circuits connected to the second gating module 22 are refreshed normally.

For example, if the scanning signal transmitted by the first gating module 21 to the corresponding pixel driving circuits does not include a valid level signal, the pixel driving circuits connected to the first gating module 21 are not refreshed. The scanning signal output by the second gating module 22 to the corresponding pixel driving circuits includes a valid level signal, then the normal refresh of the pixel driving circuits corresponding to the second gating module 22 is achieved.

In this way, by controlling the output signals of the first gating module 21 and the second gating module 22 in the shift register, the different refresh requirements of different pixel driving circuits connected to the same shift register are met, and there is no need to introduce different shift registers for pixel driving circuits with different refresh requirements, which is beneficial to reducing the actual number of shift registers included in the gate driving circuit, simplifying the panel structure, and achieving a narrow frame design.

In some embodiments, in at least one display frame, the two gating modules in a shift register are configured to receive the same frequency control signal. For example, the frequency control signals received by the first gating module 21 and the second gating module 22 are both high-level signals, or both are low-level signals. Assuming that the received frequency control signal is a low-level signal, the scanning signal output by the corresponding gating module includes a valid level signal, and the corresponding pixel driving circuits can be refreshed normally. When the received frequency control signal is a high-level signal, the scanning signal output by the corresponding gating module merely includes an invalid level signal, and the corresponding pixel driving circuits are not refreshed. Therefore, when both gating modules receive low-level signals, the pixel driving circuits corresponding to the two gating modules can be refreshed normally, and when both gating modules receive high-level signals, the pixel driving circuits corresponding to the two gating modules do not need to be refreshed. The pixel driving circuits connected to the two gating modules in the same shift register corresponding to this embodiment do not need to be refreshed differentially.

Therefore, the scheme of introducing at least two gating modules in a same shift register in the disclosed embodiments can meet the differentiated refresh requirements of different display areas, and can also meet the same refresh requirements of different display areas, which is beneficial to meet the different display requirements of a display panel.

In some embodiments, in at least one display frame, in at least one shift register, the scanning signals transmitted by the first gating module 21 and the second gating module 22 to the corresponding pixel driving circuits all include valid level signals, or do not include valid level signals. When the scanning signals transmitted by the first gating module 21 and the second gating module 22 to the corresponding pixel driving circuits all include valid signals, the pixel driving circuits corresponding to the first gating module 21 and the second gating modules can be refreshed normally. When the scanning signals transmitted by the first gating module 21 and the second gating module 22 to the corresponding pixel driving circuits do not include valid level signals, that is, when both are invalid level signals, the pixel driving circuits corresponding to the first gating module 21 and the second gating module 22 do not need to be refreshed. In other words, the pixel driving circuits corresponding to the first gating module 21 and the second gating module 22 can also be refreshed according to same refresh requirements.

The approach of simultaneously introducing the first gating module 21 and the second gating module 22 in a same shift register can meet the differentiated refresh requirements of different display areas, and can also meet the same refresh requirements of different display areas, thereby meeting the different display requirements of the display panel.

Referring to FIGS. 3, 5, and 6, in some embodiments, a pixel driving circuit P0 includes a first control signal terminal S1N and a second control signal terminal S2N, and the first control signal terminal S1N and the second control signal terminal S2N are configured to receive scanning signals output by different shift registers 01.

It should be noted that, in order to simplify the description, the signal terminals and the signals transmitted by the signal terminals are represented by the same reference numerals in the embodiments of the present disclosure. The first control signal terminal S1N in the pixel driving circuit P0 can be regarded as a signal terminal connected to the gate of the fifth transistor M5. The signal of the first control signal terminal S1N is used to control the conduction state of the fifth transistor M5. When the fifth transistor M5 is turned on, the gate of the driving transistor can be reset.

The second control signal terminal S2N can be regarded as a signal terminal connected to the gate of the fourth transistor M4 in the pixel driving circuit. The signal of the second control signal terminal S2N is used to control the conduction state of the fourth transistor M4. When the signal of the second control signal terminal S2N controls the fourth transistor M4 to be turned on and the signal of the control signal terminal SP controls the second transistor M2 to be turned on, data writing and threshold compensation of the driving transistor can be achieved.

When the pixel driving circuit is in operation, and the pixel driving circuit is refreshed normally, the fifth transistor M5 will be turned on earlier than the fourth transistor M4, that is, the timing when the gate of the fifth transistor M5 receives the valid level signal is earlier than the timing when the gate of the fourth transistor M4 receives the valid level signal. The gate of the driving transistor is reset first, and then the data writing and threshold compensation stage is performed. Therefore, in a same pixel driving circuit, the gate of the first transistor M5 (corresponding to the first control signal terminal S1N) and the gate of the fourth transistor M4 (corresponding to the second control signal terminal S2N) are respectively connected to different shift registers, and the scanning signal is provided by different shift registers.

In a same shift register 01, the first gating module 21 and the second gating module 22 are respectively used to connect different control signal terminals in the pixel driving circuits. For example, the first gating module 21 is configured to connect to the first control signal terminal S1N to control whether to reset the gate of the driving transistor of a pixel driving circuit, and the second gating module 22 is configured to connect to the second control signal terminal S2N to control the conduction state of the fourth transistor M4.

In the embodiments of the present disclosure, when the first control signal terminal S1N and the second control signal terminal S2N in a pixel driving circuit are configured to receive the scanning signals output by different shift registers 01, the output of the corresponding gating modules can be controlled by the frequency control signals. Thus, the first control signal terminal S1N and the second control signal terminal S2N in the pixel driving circuit can both receive the valid level signal in the scanning signal to achieve refresh, or both receive the invalid level signal in the scanning signal to not refresh.

FIGS. 3 and 5 illustrate a mode in which one gating module in the shift register is electrically connected to only one row of pixel driving circuits, that is, one gating module drives one row of pixel driving circuits. In this mode, the load of the gating module is small, which is conducive to improving the driving capability.

Referring to FIGS. 3 and 5, when one gating module drives one row of pixel driving circuits, the (n+1)-th stage shift register can be set on one side or both sides of the pixel driving circuits of the n-th row, the first control signal terminals S1N corresponding to the pixel driving circuits of the n-th row are connected to the output terminal of the first gating module 21 in the n-th stage shift register. The second control signal terminals S2N of the pixel driving circuits of the n-th row are connected to the output terminal of the second gating module 22 in the (n+1)-th stage shift register.

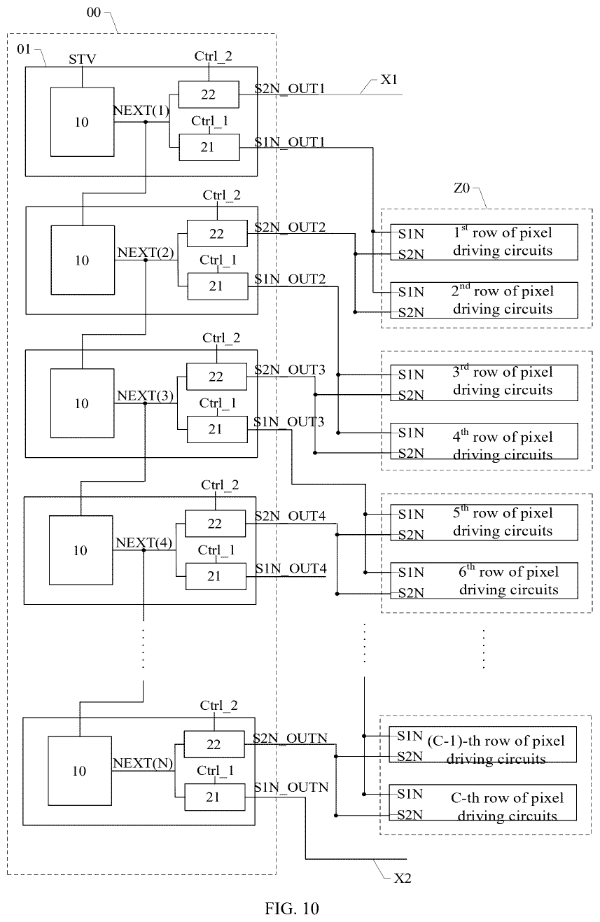

In some embodiments of the present disclosure, a gating module in a shift register may also be connected to at least two rows of pixel driving circuits. For example, FIG. 10 illustrates another connection diagram of the shift register and the pixel driving circuits in the gate driving circuit. In the pixel driving circuits of the s-th row and the p-th row, the second control signal terminals S2N are connected to the output terminal of the second gating module 22 in the m-th stage shift register. The first control signal terminals S1N are connected to the output terminal of the first gating module 21 in the n-th stage shift register, where s≥1, p≥1, s≠p, and m>n≥1.

For example, referring to FIG. 10, the first control signal terminals S1N of the pixel driving circuits of the first row and the second row are both connected to the output terminal of the first gating module 21 in the first-stage shift register, and the second control signal terminals S2N of the pixel driving circuits of the first row and the second row are both connected to the output terminal of the second gating module 22 in the second stage shift register.

In the disclosed embodiments, the pixel driving circuits of the s-th row and the p-th row can be any two rows of pixel driving circuits in the display panel, and the two rows of pixel driving circuits can be adjacent or not adjacent. FIG. 10 merely takes the two rows of adjacent pixel driving circuits as an example for schematic purposes, but the present disclosure is not limited thereto.

The second control signal terminals S2N in the two rows of pixel driving circuits are connected to a same shift register, and the first control signal terminals S1N in the two rows of pixel driving circuits are connected to another shift register, so that the gate resetting process of the driving transistors in the two rows of pixel driving circuits is carried out simultaneously, and the threshold compensation and data writing process in the two rows of pixel driving circuits is also carried out simultaneously. A same shift register is used to drive the two rows of pixel driving circuits, and there is no need to introduce different shift registers for the pixel driving circuits of different rows, respectively. Thus, it is conducive to simplifying the actual number of shift registers included in the gate driving circuit, reducing the actual space occupied by the gate driving circuit in the display panel, and thus it is conducive to achieving the narrow frame design of the display panel.

It should be noted that, in the pixel driving circuits of the s-th row and the p-th row, the shift register connected to the first control signal terminals S1N is different from the shift register connected to the second control signal terminals S2N. The first control signal terminals S1N are connected to the output terminal of the first gating module 21 in the n-th stage shift register, and the second control signal terminals S2N are connected to the output terminal of the second gating module 22 in the m-th stage shift register, and n<m. That is, the n-th stage shift register outputs the scanning signal first, and the m-th stage shift register outputs the scanning signal later.

In this way, during actual refreshing, it is possible to first send the valid level signal in the scanning signal to the first control signal terminals S1N, to complete the gate resetting of the driving transistors of the two rows of pixel driving circuits, and then send the valid level in the scanning signal to the second control signal terminals S2N to complete the threshold voltage compensation. Apparently, when refreshing is not required, the n-th stage shift register first sends the invalid level signal in the scanning signal to the first control signal terminals S1N, and the shift register of the m-th stage then sends the invalid level signal in the scanning signal to the second control signal terminals S2N. It should be noted that in an actual display panel, the pixel driving circuits of the s-th row and the p-th row have the same refresh requirements, for example, both need to be refreshed, or both do not need to be refreshed.

Optionally, in the above embodiment, p=s+1, m−n=1, in other words, when a same shift register is used to drive two rows of pixel driving circuits, the two rows of pixel driving circuits can be, for example, two adjacent rows. In an actual panel, for example, the pixel driving circuits of the 1st and 2nd rows are taken as a whole, the pixel driving circuits of the third and fourth rows are taken as a whole, and so on. This is conducive to simplifying the connection between the pixel driving circuits of different rows and the shift registers.

When m−n=1, the shift register representing the n-th stage and the shift register representing the m-th stage are adjacent, that is, the two stage shift registers that respectively provide scanning signals to the first control signal terminals S1N and the second control signal terminals S2N of the two adjacent rows of pixel driving circuit are adjacent-stage shift registers. This is conducive to reducing the interval between the gate reset stage of the driving transistors and the data writing and threshold compensation stage in the pixel driving circuits, and is conducive to improving the working efficiency of the pixel driving circuits.

FIG. 10 illustrates the connection relationship between the pixel driving circuits of the adjacent s-th row, p-th row and the shift registers. For the connection relationship of the pixel driving circuits after the p-th row, it can refer to the connection relationship between the pixel driving circuits of the s-th row and the p-th row. For example, in some embodiments, in the pixel driving circuits of the (p+1)-th row and the (p+2)-th row (the third row and the fourth row of pixel driving circuits may be taken as example), the second control signal terminals S2N are connected to the output terminal of the second gating module 22 in the (m+1)-th stage shift register, and the first control signal terminals S1N are connected to the output terminal of the first gating module 21 in the m-th stage shift register. That is, the pixel driving circuits of the (p+1)-th row and the (p+2)-th row are taken as a whole. Each first control signal terminal S1N receives the scanning signal output by the first gating module 21 in the m-th stage shift register to determine whether to reset the gate of the driving transistor. Each second control signal terminal S2N receives the scanning signal output by the second gating module 22 in the (m+1)-th stage shift register to determine whether to turn on the fourth transistor M4 in the pixel driving circuit shown in FIG. 6 or FIG. 7.

When the pixel driving circuits of the s-th and p-th rows are taken as a whole, and the pixel driving circuits of the (p+1)-th and (p+2)-th rows are taken as another whole, it is possible to achieve that the pixel driving circuits of the s-th and p-th rows are refreshed normally, and the pixel driving circuits of the (p+1)-th and (p+2)-th rows are not refreshed, or that the pixel driving circuits of the s-th and p-th rows are not refreshed, and the pixel driving circuits of the (p+1)-th and (p+2)-th rows are refreshed normally.

Take the pixel driving circuits of the s-th and p-th rows being refreshed normally, and the pixel driving circuits of the (p+1)-th and (p+2)-th rows being not refreshed as an example. The first gating module 21 in the n-th stage shift register outputs a scanning signal including a valid signal to the first control signal terminals S1N of the pixel driving circuits of the s-th and p-th rows, which reset the gates of the driving transistors of the pixel driving circuits of the s-th and p-th rows. The second gating module 22 in the m-th stage shift register outputs a scanning signal including a valid level signal to the second control signal terminals S2N of the pixel driving circuits of the s-th and p-th rows, which compensates for the threshold voltage, thereby achieving the refreshing of the pixel driving circuits of the s-th and p-th rows.

The scanning signal outputted by the first gating module 21 in the m-th stage shift register to the pixel driving circuits of the (p+1)-th row and the (p+2)-th row and the scanning signal outputted by the second gating module 22 of the shift register of the (m+1)-th stage to the pixel driving circuits of the (p+1)-th row and the (p+2)-th row do not include a valid level signal, and thus the pixel driving circuits of the (p+1)-th row and the (p+2)-th row are not refreshed. When the pixel driving circuits of the s-th row and the p-th row are refreshed and the pixel driving circuits of the (p+1)-th row and the (p+2)-th row are not refreshed, the first control signal terminal S1N and the second control signal terminal S2N of the corresponding pixel driving circuit can both receive the correct scanning signal, thereby avoiding the problem of abnormal display of the display panel in the regional refresh stage.

Referring to FIG. 10, in some embodiments, in at least one display frame, the scanning signals received by the first control signal terminals S1N and the second control signal terminals S2N in the pixel driving circuits of the same row all include valid level signals. That is, when a certain row of pixel driving circuits needs to be refreshed normally, the first control signal terminals S1N and the second control signal terminals S2N of the pixel driving circuits of the row can receive the signal that normally controls them to refresh. The problem occurred in the existing technologies, that one of the first control signal terminal S1N and the second control signal terminal S2N receives an incorrect refresh signal, will not occur.

Similarly, when a certain row of pixel driving circuits do not need to be refreshed, the scanning signals received by the first control signal terminals S1N and the second control signal terminals S2N in the pixel driving circuits of the same row do not include valid level signals. The problem that occurred in the existing technologies, that one of the first control signal terminal S1N and the second control signal terminal S2N receives a valid level signal and causes a display error, will not occur.

Referring to FIGS. 3 and 10, the display panel includes C circuit groups Z0, where C≥1. A circuit group Z0 includes a plurality of pixel driving circuits, and one of the circuit groups Z0 includes at least one row of pixel driving circuits. In the embodiment shown in FIG. 3, one circuit group Z0 includes a row of pixel driving circuits, and in the embodiment shown in FIG. 10, one circuit group Z0 includes two adjacent rows of pixel driving circuits.

A pixel driving circuit includes a first control signal terminal S1N and a second control signal terminal S2N, and the first control signal terminal S1N and the second control signal terminal S2N are configured to receive scanning signals output by different shift registers. In one circuit group Z0, the first control signal terminals S1N of the pixel driving circuits are connected to the output terminal of the first gating module 21 in one shift register 01, and the second control signal terminals S2N of the pixel driving circuits are connected to the output terminal of the second gating module 22 in another shift register 01. The number of shift registers included in a group of gate driving circuits is N≥C+1. That is, when the number of circuit groups in the display panel is C, the number N of shift registers included in the group of gate driving circuits is at least C+1. The present disclosure takes N=C+1 as an example for explanation, but is not limited thereto. In some embodiments of the present disclosure, the number N of shift registers included in a group of gate driving circuits may also be greater than C+1. It can be understood that a shift register needs to provide corresponding scanning signals to pixel circuits of different rows through the first gating module 21 and the second gating module 22. At the same time, the first control signal terminals S1N and the second control signal terminals S2N of the pixel driving circuits in a circuit group are also provided with scanning signals by different shift registers. In this way, it may happen that the first signal control terminals S1N or the second signal control terminals S2N in some circuit groups do not have a corresponding shift register to provide a scanning signal. In the embodiments of the present disclosure, setting the number of shift registers to be greater than the number of circuit groups can ensure that the first control signal terminal S1N and the second control signal terminal S2N of each pixel driving circuit are provided with corresponding scanning signals, so as to ensure that the display panel can display normally.

When the number of shift registers included in a group of gate driving circuits is set to be at least one more than the number of circuit groups, the extra shift register can act as a buffer to ensure that the signal has enough time to stabilize during transmission and avoid data errors caused by sequence deviations. In addition, in high-speed refresh operations, the extra shift register can provide an additional clock cycle to compensate for signal delays, so that the scanning signals output by shift registers of different levels can be generated and processed in the same way, reducing circuit complexity.

Taking FIG. 10 as an example, when N=C+1, the first control signal terminals S1N of the pixel driving circuits of the first and second rows are connected to the output terminals of the first gating module 21 of the first-stage shift register, and the second control signal terminals S2N of the pixel driving circuits of the first and second rows are connected to the output terminal of the second gating module 22 of the second-stage shift register. At this time, the output terminal of the second gating module 22 of the first-stage shift register is not connected to the pixel driving circuits.

Optionally, in a gate driving circuit, the output terminal of the second gating module 22 in at least the first-stage shift register is floating or connected to the first signal line X1, and the first signal line X1 is not connected to the pixel driving circuits. That is, the output end of the second gating module 22 in the first-stage shift register may not be connected to any other signal, or a first signal line X1 may be introduced in the display panel to be connected to the output end of the second gating module 22. The first signal line X1 may be regarded as a virtual signal line that is not connected to the pixel driving circuits. The first signal line X1 may receive a fixed-level signal in the display panel, such as a high-level signal or a low-level signal, or other fixed potential signals in the display panel. This is helpful in preventing static electricity from affecting the normal operation of the shift register through the output end of the second gating module 22.

For the shift register located at the last stage, the output end of the second gating module 22 is electrically connected to the second control signal terminal S2N of the last two rows of pixel driving circuits in the display panel, and the output end of the first gating module 21 in the last stage shift register is not connected to the pixel driving circuits. At this time, at least the output end of the first gating module 21 in the last stage shift register is floating or connected to a second signal line X2, and the second signal line X2 is not connected to the pixel driving circuits. When the first gating module 21 is floating, the output end of the first gating module 21 may not be connected to any other signal. When the output end of the first gating module 21 is connected to the second signal line X2, the second signal line X2 can be regarded as a virtual signal line that is not connected to the pixel driving circuits. The second signal line X2 can receive a fixed level signal in the display panel, such as a high-level signal or a low-level signal, which is conducive to preventing static electricity from affecting the normal operation of the shift register through the output end of the first gating module 21.

Optionally, the first signal line X1 and the second signal line X2 may be the same signal line, for example, both are high-level signal lines that receive high-level signals, or both are low-level signal lines that receive low-level signals.

Optionally, the first signal line X1 and the second signal line X2 may be different signal lines, for example, one is a high-level signal line that receives high-level signals, and the other is a low-level signal line that receives low-level signals. Here, the high-level signal may be a high-level signal VGH described later, and the low-level signal may be a low-level signal VGL described later.

It should be noted that when the output end of the second gating module 22 of the first-stage shift register is floating, the output end of the first gating module 21 in the last-stage shift register may be floating, or connected to the second signal line X2 receiving a fixed potential signal. When the output end of the second gating module 22 of the first-stage shift register is connected to the first signal line X1 receiving a fixed potential signal, the output end of the first gating module 21 in the last-stage shift register may be floating, or connected to the second signal line X2 receiving a fixed potential signal, which is not specifically limited in the present disclosure.

The embodiments of the present disclosure introduce a first gating module 21 and a second gating module 22 for different shift registers, respectively, which are configured to be electrically connected to the first control signal terminals S1N and the second control signal terminals S2N of the pixel driving circuits of different rows, and output scanning signals to the corresponding first control signal terminals S1N and the second control signal terminals S2N respectively.

In some embodiments, in a shift register, the first gating module 21 and the second gating module 22 have the same circuit structure. The same circuit structure mentioned here, for example, can be that the number of transistors included in the first gating module 21 and the second gating module 22 is the same, and the connection relationship between the transistors is the same.

Considering that the first gating module 21 and the second gating module 22 have the same function and only the connected signal terminals are different. When the first gating module 21 and the second gating module 22 are formed by the same circuit structure, there is no need to introduce different circuits for the first gating module 21 and the second gating module 22, respectively, which is conducive to simplifying the overall circuit structure of the shift register.

It should be noted that in the actual circuit layout, the circuit layout of the first gating module 21 and the second gating module 22 can be selected to be the same, or can be selected to be different according to actual needs, which is not specifically limited in the present disclosure. In subsequent embodiments, the feasible circuit structures of the stage transmission module 10, the first gating module 21, and the second gating module 22 will be illustrated by examples.

FIG. 10 illustrates a scheme in which a group of gate driving circuits provide scanning signals to the first control signal terminals S1N and the second control signal terminals S2N in the same row of pixel driving circuits. In some embodiments of the present disclosure, the first control signal terminals S1N and the second control signal terminals S2N in the same row of pixel driving circuits may also be driven by two groups of gate driving circuits respectively. For example, referring to FIG. 11, which is another connection diagram of a shift register in the gate driving circuit and the pixel driving circuits.

In some embodiments, the display panel includes two groups of gate driving circuits 00, and a pixel driving circuit includes a first control signal terminal S1N and a second control signal terminal S2N. The first control signal terminals S1N of the pixel driving circuits in the same row are electrically connected to the shift register 01 at the same stage in the two groups of gate driving circuits 00, and the second control signal terminals S2N of the pixel driving circuits in the same row are electrically connected to the shift register 01 at the same stage in the two groups of gate driving circuits 00. The two shift registers 01 connected to the pixel driving circuits in the same row are respectively located on two opposite sides of the pixel driving circuits in the row.

The illustrated embodiment illustrates a scheme in which two groups of gate driving circuits 00 are introduced on both sides of an array formed by pixel driving circuits, and the two groups of gate driving circuits jointly drive the pixel driving circuits. Taking the first row of pixel driving circuits as an example, each first control signal terminal S1N is respectively connected to the first gating module 21 in the first-stage shift register 01 in the two groups of gate driving circuits 00, and the two first gating modules 21 jointly provide scanning signals to each first control signal terminal S1N in the first row of pixel driving circuits. It is conducive to improving the overall driving capability of the panel, and improving the scanning efficiency and scanning effect of the pixel driving circuits.

In particular, for the scheme in which a single shift register drives two rows of pixel driving circuits, since the number of pixel driving circuits loaded by a single shift register 01 is large, there may be a problem of weak driving capability. At this time, when two groups of gate driving circuits 00 are introduced to drive the pixel driving circuits, it is conducive to improving the overall driving capability of the gate driving circuits to the pixel driving circuits, and meeting the driving requirements of the display panel.

Referring to FIGS. 6 and 11, in one embodiment of the present disclosure, a pixel driving circuit includes a driving transistor (the third transistor M3 is used as an example in the figures for schematic purposes), a reset module 71 (the fifth transistor M5 is configured as an example in the figures for schematic purposes) and a threshold compensation module 72 (the fourth transistor M4 is used as an example in the figures for schematic purposes). The reset module 71 is connected between the reset signal terminal Vref1 and the gate of the driving transistor M3, and the threshold compensation module 72 is connected between the gate of the driving transistor M3 and the first electrode of the driving transistor M3. The control end of the reset module 71 is connected to the first control signal terminal S1N, and the control end of the threshold compensation module 72 is connected to the second control signal terminal S2N. In a pixel driving circuit, the first control signal terminal S1N receives a scanning signal output by a first gating module 21 of a shift register, and the second control signal terminal S2N receives a scanning signal output by a second gating module 22 of another shift register.

In the embodiments of the present disclosure, the shift register introduced into the stage transmission module 10, the first gating module 21 and the second gating module 22 refers to a shift register that outputs scanning signals to the first control signal terminals S1N and the second control signal terminals S2N in the pixel driving circuits. The gate driving circuit mentioned in the embodiments of the present disclosure refers to a gate driving circuit that outputs scanning signals to the first control signal terminals S1N and the second control signal terminals S2N in the pixel driving circuits.

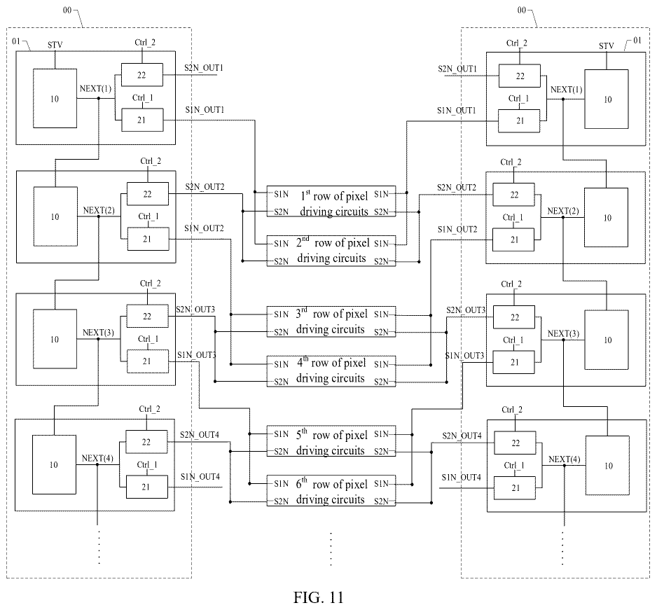

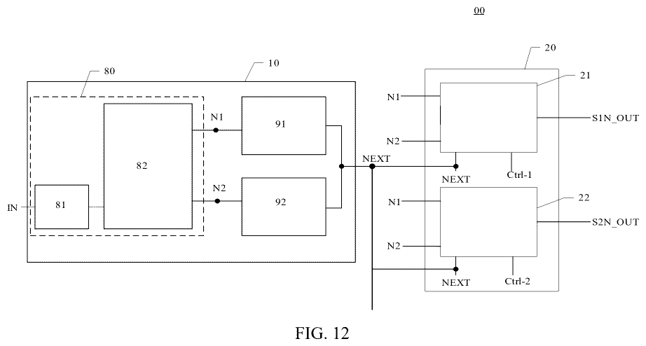

FIG. 12 illustrates a schematic structural diagram of a gate driving circuit in accordance with an embodiment of the present disclosure. Referring to FIG. 12, the stage transmission module 10 includes a control unit 80, a first output component 91 and a second output component 92 electrically connected to the control unit 80. The first output component 91 and the control unit 80 are connected to a first node N1, and the second output component 92 and the control unit 80 are connected to a second node N2. The first output component 91 and the second output component 92 output the stage transmission signal NEXT according to the signal of the first node N1 and the signal of the second node N2. In the illustrated embodiment, the gating module 20 is configured to output a scanning signal according to the frequency control signal Ctrl, the signal of the first node N1, the signal of the second node N2, and the stage transmission signal NEXT. In the illustrated embodiment, the gating module 20 also receives the stage transmission signal NEXT.

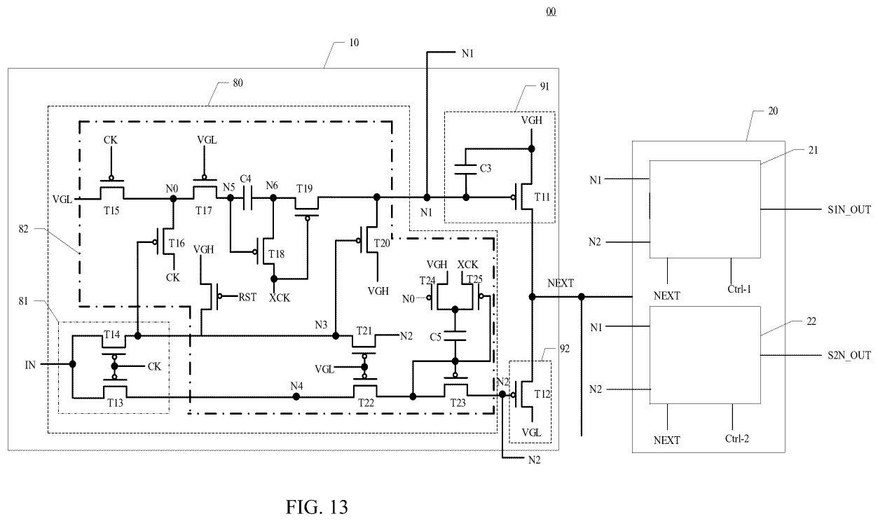

FIG. 13 illustrates a schematic structural diagram of a gate driving circuit in accordance with an embodiment of the present disclosure. In combination with FIGS. 12 and 13, the illustrated embodiment refines the structure of the stage transmission module 10. Optionally, the control unit 80 in the stage transmission module 10 includes a first control module 81 and a second control module 82. The first control module 81 is configured to receive the input signal IN and control the signals of the third node N3 and the fourth node N4 in response to the first clock signal CK. The signal of the third node N3 is connected to the second node N2. The second control module 82 is configured to receive the voltage signal VGH and the voltage signal VGL, and control the signal of the first node N1 in response to the signal of the third node N3, the signal of the fourth node N4, the first clock signal CK and the second clock signal XCK.

Exemplarily, the first control module 81 includes a transistor T13 and a transistor T14, where the first electrode of the transistor 13 is connected to the input signal terminal IN, the second electrode is connected to the fourth node N4, and the gate is connected to the first clock signal CK. The first electrode of the transistor T14 is connected to the input signal terminal IN, the second electrode is connected to the third node N3, and the gate is connected to the first clock signal CK.

Exemplarily, the second control module 82 includes transistors T15 to T25, capacitor C4 and capacitor C5. The first electrode of the transistor T15 receives a low-level signal VGL, the gate receives a first clock signal CK, and the second electrode is connected to node N0. The gate of the transistor T16 is connected to the third node N3, the first electrode receives the first clock signal CK, and the second electrode is connected to node N0. The first electrode of the transistor T17 is connected to node N0, the gate receives a low-level signal VGL, the second electrode is connected to the first electrode plate of the capacitor C4, and the second electrode plate of capacitor C4 is connected to the first electrode of the transistor T19. The first electrode of the transistor T18 receives a second clock signal XCK, the gate is connected to the first electrode plate of the capacitor C4, and the second electrode is connected to the first electrode of the transistor T19. The second electrode of the transistor T19 is connected to the first node N1, and the gate receives the second clock signal XCK. The first electrode of the transistor T20 receives a high-level signal VGH, and the second electrode is connected to the first node N1, the gate is connected to the third node N3. The first electrode of the transistor T21 is connected to the third node N12, the second electrode is connected to the second node N2, and the gate receives a low-level signal VGL. The first electrode of the transistor T22 is connected to the fourth node N4, the second electrode is connected to the first electrode of the transistor T23, and the gate receives a low-level signal VGL. The first electrode and the gate of the transistor T23 are connected to the second electrode of the transistor T22, and the second electrode of the transistor T23 is connected to the second node N2. The first electrode plate of the capacitor C5 is connected to the gate of the transistor T23, and the second electrode plate is connected to the second electrodes of the transistors T24 and T25. The first electrode of the transistor T24 receives a low-level signal VGL, and the gate is connected to the node N0. The first electrode of T25 receives the second clock signal XCK, and the gate is connected to the first electrode of the transistor M23.

Exemplarily, the first output component 91 includes a transistor T11 and a capacitor C3, and the second output component 92 includes a transistor T12. The gate of the transistor T11 is connected to the first node N1, the first electrode receives a high-level signal VGH, and the second electrode outputs a stage transmission signal NEXT. The first electrode plate of the capacitor C3 receives a high-level signal VGH, and the second plate is connected to the gate of the transistor T11. The gate of the transistor T12 is connected to the second node N2, the first electrode receives a low-level signal VGL, and the second electrode outputs a stage transmission signal NEXT.

It should be noted that the circuit structure of the stage transmission module shown in FIG. 13 is merely for schematic purposes and does not specifically limit the specific structure of the stage transmission module. In some embodiments of the present disclosure, the stage transmission module may also adopt other feasible circuit structures.

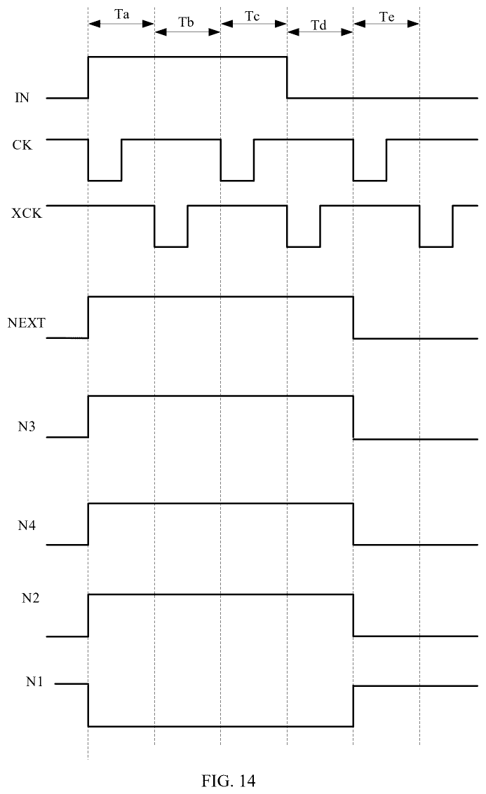

FIG. 14 is a driving sequence diagram of the stage transmission module 10 of the shift register in FIG. 13. The working principle and process of the stage transmission module 10 in the disclosed embodiments will be introduced below in combination with FIGS. 13 and 14.

In the Ta stage, the input signal IN is at a high level and the first clock signal CK is at a low level. At this time, the transistors T13, T14 and T15 are turned on, and the input signal IN is transmitted to the third node N3 and the fourth node N4 respectively through the transistors T13 and T14, so that the third node N3 and the fourth node N4 are both at a high level, and the transistors T16 and T20 are turned off. At the same time, a low-level signal VGL is transmitted to the node N0 through the transistor T15, the node N0 is at a low level, and the transistor T17 is normally turned on. Then the node N5 is at a low level, the transistor T18 is turned on, the second clock signal XCK is at a high level, the node N6 remains at a high level, the transistor T19 is turned off. The first node N1 remains at a low level, the transistor T11 is turned on, and a high-level signal VGH is transmitted to the output end, so that the stage transmission signal NEXT is at a high level.

In the Tb stage, the input signal IN is at a high level, and the first clock signal CK is at a high level. At this time, the transistors T13, T14 and T15 are turned off, the third node N3 and the fourth node N4 remain at a high level, the transistors T16 and T20 are turned off, the node N0 remains at a low level, the transistor T18 is turned on, the second clock signal XCK is at a low level, and is transmitted to the node N6 through the transistor T18. Thus, the node N6 is at a low level, the transistor T19 is turned on, the signal of the node N6 is transmitted to the first node N1, the transistor T11 is turned on, and the high level signal VGH is transmitted to the output end, so that the stage transmission signal NEXT is at a high level.

In the Tc stage, the input signal IN is at a high level, and the first clock signal CK is at a low level. At this time, the transistors T13, T14 and T15 are turned on, and the input signal IN is transmitted to the third node N3 and the fourth node N4 respectively through the transistors T13 and T14, so that the third node N3 and the fourth node N4 are both at a high level, and the transistors T16 and T20 are turned off. At the same time, a low-level signal VGL is transmitted to the node N0 through the transistor T15, the node N0 is at a low level, and the transistor T17 is normally turned on. Then the node N5 is at a low level, the transistor T18 is turned on, the second clock signal XCK is at a high level, the node N6 remains at a high level, the transistor T19 is turned off, the first node N1 remains at a low level, the transistor T11 is turned on, and a high-level signal VGH is transmitted to the output end, so that the stage transmission signal NEXT is at a high level.

In the Td stage, the input signal IN is at a low level, the first clock signal CK is at a high level. At this time, the transistors T13, T14 and T15 are all turned off, the third node N3 and the fourth node N4 are both kept at a high level, and the transistors T16 and T20 are both turned off. The node N0 is kept at a low level, and the transistor T17 is normally turned on, then the node N5 is at a low level, the transistor T18 is turned on, the second clock signal XCK is at a low level, and the second clock signal XCK is transmitted to the node N6 through the transistor T18, so that the node N6 is at a low level. At the same time, the transistor T19 is turned on, the signal of the node N6 is transmitted to the first node N1 at a low level, the transistor T11 is turned on, and a high-level signal VGH is transmitted to the output end, so that the stage transmission signal NEXT is at a high level.

In the Te stage, the input signal IN is at a low level, the first clock signal CK is at a low level. At this time, the transistors T13, T14 and T15 are turned on, the input signal IN is transmitted to the third node N3 and the fourth node N4 respectively through the transistors T13 and T14, so that the third node N3 and the fourth node N4 are both at a low level, and the transistors T16 and T20 are turned on. At the same time, the transistor T15 is turned on, a low-level signal VGL is transmitted to the node N0 through the transistor T15, the node N0 is at a low level, and the transistor T17 is normally turned on. Then the node N5 is at a low level, transistor T18 is turned on, the second clock signal XCK is high, the node N6 maintains a high level, and the transistor T19 is turned off. The transistor T20 is turned on, and a high-level signal VGH is transmitted to the first node N1 through the transistor T20, so that the first node N1 is high level, and the transistor T11 is turned off. At the same time, the transistor T21 and the transistor T22 are normally turned on, and the signal of the third node N3 is transmitted to the second node N2, so that the second node N2 is low level. The transistor T12 is turned on, and a low-level signal VGL is transmitted to the output end, so that the stage transmission signal NEXT is low level.

It can be seen that in the Ta-Td stage, when the stage transmission signal NEXT is output at a high level, one of the first node N1 and the second node N2 is at a low level and the other is at a high level. The embodiments of the present disclosure are explained by taking the first node N1 at a low level and the second node N2 at a high level as an example.

Referring to FIGS. 12 and 13, in the illustrated embodiment, the first gating module 21 and the second gating module 22 are electrically connected to the first node N1 and the second node N2 in the stage transmission module 10, respectively, and also receive the stage transmission signal NEXT and the frequency control signal Ctrl_1/Ctrl_2 respectively. The first gating module 21 and the second gating module 22 can output the scanning signal according to the frequency control signal Ctrl_1/Ctrl_2, the signal of the first node N1, the signal of the second node N2, and the stage transmission signal NEXT. The specific structure of the gating module will be described below.

Referring to FIG. 15, which is a schematic structural diagram of the first gating module 21 and the second gating module 22 in accordance with an embodiment of the present disclosure. In conjunction with FIGS. 13 and 15, in some embodiments, the gating module includes a first output unit 31, a second output unit 32, an isolation protection unit 33 and an output control unit 34. The control end of the isolation protection unit 33 receives the stage transmission signal NEXT, the input end of the isolation protection unit 33 receives the frequency control signal Ctrl_1/Ctrl_2, and the output end of the isolation protection unit 33 is connected to the control end of the output control unit 34. The input end of the output control unit 34 receives the signal of the first node N1, and the output end is connected to the control end of the first output unit 31. The input end of the first output unit 31 receives a first level signal VGH, and the output end is connected to the output end S1N_OUT/S2N_OUT of the gating module. The control end of the second output unit 32 receives the signal of the second node N2, the input end receives a second level signal VGL, and the output end is connected to the output end S1N_OUT/S2N_OUT of the gating module.

Optionally, the gating module further includes a node control module 35, the control end of the node control module 35 receives the signal of the first node N1, the input end receives a first level signal VGH, and the output end is connected to the control end of the first output unit 31, and is configured to control the signal of the control end of the first output unit 31.

Optionally, a capacitor may be introduced between the control end of the first output unit 31 and a first level signal end VGH, which may also play a role in maintaining the signal of the control end of the first output unit 31.

Exemplarily, the isolation protection unit 33 includes a transistor T3 and a capacitor, and the output control unit 34 includes a transistor T4. The first output unit 31 includes a transistor T1, and the second output unit 32 includes a transistor T2, where the gate of the transistor T3 receives a stage transmission signal, the first electrode receives a frequency control signal Ctrl_1/Ctrl_2, and the second electrode is connected to the gate of the transistor T4. The first electrode of the transistor T4 is connected to the first node N1 in the stage transmission module 10, the second electrode is connected to the gate of the transistor T1. The first electrode of the transistor T1 receives a first level signal VGH, and the second electrode is connected to the output end of the gating module. The gate of the transistor T2 is connected to the first node in the stage transmission module 10, the first electrode receives a second level signal VGL, and the second electrode is connected to the output end S1N_OUT/S2N_OUT of the gating module.

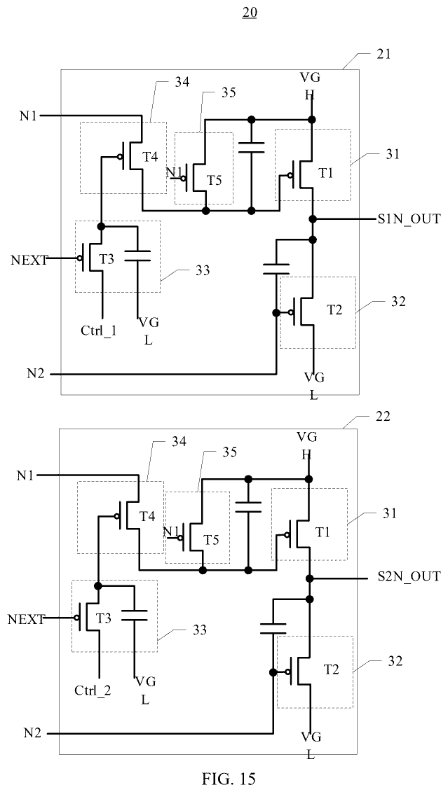

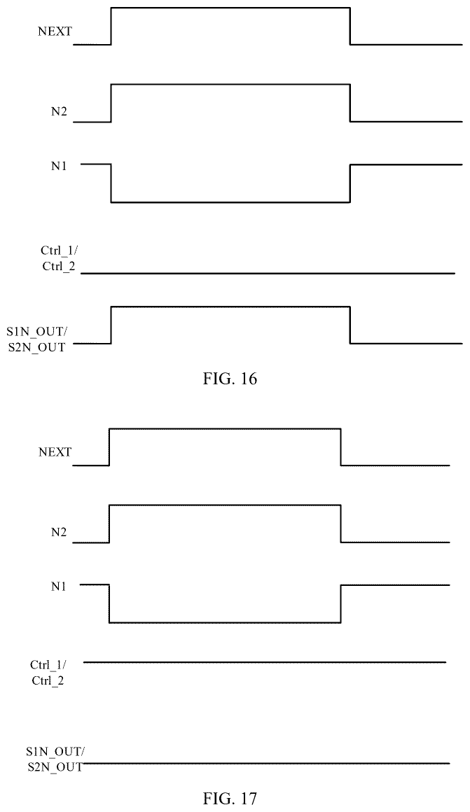

FIG. 16 is a working sequence diagram of the gating module in FIG. 15, which reflects the working condition of the gating module when the frequency control signal Ctrl_1/Ctrl_2 is a low-level signal. Referring to FIGS. 15 and 16, in the stage where the output of the stage transmission signal is at a low level, the transistor T3 is turned on, and the low-level signal of the frequency control signal is transmitted to the gate of the transistor T4 through the transistor T3, controlling the transistor T4 to be turned on. The high-level signal of the first node N1 is transmitted to the transistor T1 through the transistor T4, so that the transistor T1 is turned off. The low-level signal of the second node N2 is transmitted to the transistor T2, and the transistor T2 is turned on. A second-level signal VGL is transmitted to the output end of the gating module through the transistor T2, and the output end of the gating module outputs a low-level signal.

In the stage where the output of the stage transmission signal is at a high level, the second node N2 is at a high level, the first node N1 is at a low level, the transistor T2 is turned off, the transistor T3 is turned off, and the transistor T4 remains turned on. The low-level signal of the first node N1 is transmitted to the gate of the transistor T1, the transistor T1 is turned on, a first level signal VGH is transmitted to the output end of the gating module through the transistor T1, and the output end S1N_OUT/S2N_OUT of the gating module outputs a high-level signal. Therefore, when the frequency control signal is at a low level, the output signal of the gating module will not be affected by the frequency control signal, and the gating module can output the scanning signal normally.

FIG. 17 illustrates another working sequence diagram of the gating module in FIG. 15, which reflects the working condition of the gating module when the frequency control signal is a high-level signal. Referring to FIGS. 15 and 17, when the stage transmission signal output is a low-level stage, the transistor T3 is turned on. The high-level signal of the frequency control signal is transmitted to the transistor T4, so that the transistor T4 is turned off, and the signal of the first node N1 cannot be transmitted to the gate of the transistor T1. At this time, the potential of the second node N2 is a low level, the transistor T2 is controlled to be turned on, and a second-level signal VGL is transmitted to the output end of the gating module through the transistor T2, and the output end of the gating module outputs a low-level signal.

When the stage transmission signal leaps to a high-level signal, the transistor T3 is turned off, and the transistor T4 is maintained in the off state. The signal of the first node N1 still cannot be transmitted to the gate of the transistor T1, and the transistor T1 remains turned off. The high level of the second node N2 controls the transistor T2 to be turned off, and the output end of the gating module remains at the low level of the previous stage. Therefore, when the frequency control signal is high level, the scanning signal output by the output end of the gating module only includes an invalid level signal. Therefore, when the frequency control signal is at a low level, the gating module can output the scanning signal normally. When the frequency control signal changes from a low-level signal to a high-level signal, the gating module can only output an invalid level signal.

It should be noted that the function of the transistor T3 in the isolation protection unit 33 is to be cut off when the stage transmission signal outputs a high level. If the frequency control signal leaps, the frequency control signal cannot be written into the gate of the transistor T4 until the stage transmission signal leaps to a low level. The changed frequency control signal is then written into the gate of the transistor T4, thereby helping to avoid the problem of incomplete output signal of the gating module due to the change of the frequency control signal when the stage transmission signal is halfway transmitted.

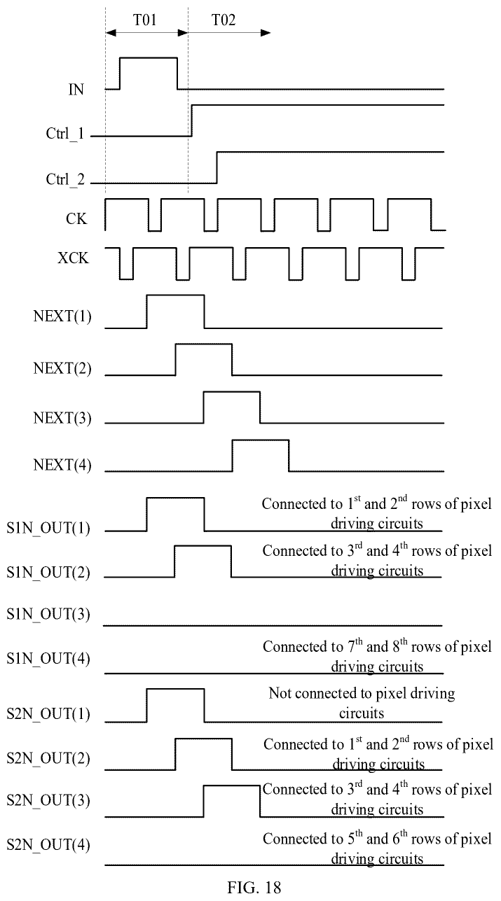

The working process of the display panel when implementing regional refresh will be explained as follows in conjunction with FIG. 18, which illustrates a driving sequence diagram of the gate driving circuit to a pixel driving circuit in accordance with an embodiment of the present disclosure. Taking the architecture shown in FIG. 11 as an example, the first-row pixel driving circuits and the second-row pixel driving circuits are taken as a whole. Each first control signal terminal S1N is connected to the output end of the first gating module 21 in a first-stage shift register, and each second control signal terminal S2N is connected to the output end of the second gating module 22 in a second stage shift register. The third-row pixel driving circuits and the fourth-row pixel driving circuits are taken as a whole. Each first control signal terminal S1N is connected to the output end of the first gating module 21 in the second stage shift register, and each second control signal terminal S2N is connected to the output end of the second gating module 22 in a third-stage shift register. The fifth-row pixel driving circuits and the sixth-row pixel driving circuits are taken as a whole, each first control signal terminal S1N is connected to the output end of the first gating module 21 in the third-stage shift register, and each second control signal terminal S2N is connected to the output end of the second gating module 22 in a fourth stage shift register.

Referring to FIG. 18, NEXT (1) to NEXT (4) represent the stage transmission signals output by the first-stage shift register to the fourth-stage shift register, respectively. S1N_OUT (1) to S1N_OUT (4) represent the scanning signals output by the output ends of the first gating modules 21 in the first-stage shift register to the fourth-stage shift register, respectively. S2N_OUT (1) to S2N_OUT (4) represent the scanning signals output by the output ends of the second gating modules 22 in the first-stage shift register to the fourth-stage shift register, respectively.

The first control signal terminals S1N of the pixel driving circuits of the first and second rows receive the signal S1N_OUT (1), and the second control signal terminals S2N receive the signal S2N_OUT (2). The first control signal terminals S1N of the pixel driving circuits of the third and fourth rows receive the signal S1N_OUT (2), and the second control signal terminals S2N receive the signal S2N_OUT (3). The first control signal terminals S1N of the pixel driving circuits of the fifth and sixth rows receive the signal S1N_OUT (3), and the second control signal terminals S2N receive the signal S2N_OUT (4).

Ctrl_1 represents the frequency control signal received by each first gating module 21 in each level of the shift register, and Ctrl_2 represents the frequency control signal received by each second gating module 22 in each level of the shift register.

In the stage where the frequency control signals Ctrl_1 and Ctrl_2 are both at a low level, the pixel driving circuits in the first and second rows and the pixel driving circuits in the third and fourth rows all receive a valid level signal in the scanning signal. When the third-stage shift register outputs a valid level signal in the stage transmission signal, the first frequency control signal Ctrl_1 has leaped from a low-level signal to a high-level signal, and the second frequency control signal Ctrl_2 is still a low-level signal. Therefore, the second gating module 22 in the third-stage shift register can still output the scanning signal including a valid level signal to the pixel driving circuits in the third and fourth rows. While the first gating module 21 outputs the scanning signal including only an invalid level signal to the pixel driving circuits in the fifth and sixth rows, and it does not reset the gates of the driving transistors in the pixel driving circuits in the fifth and sixth rows. When a valid level signal in the output stage transmission signal of the fourth-stage shift register is transmitted, the second frequency control signal has leaped from a low-level signal to a high-level signal, and the first frequency control signal is maintained as a high-level signal. The scanning signals output by the first gating module 21 and the second gating module 22 of the fourth-stage shift register only include an invalid level signal, and starting from the fifth and sixth rows of pixel driving circuits, the subsequent pixel driving circuits are all reflected as not being refreshed. In this way, the regional refresh performance of refreshing the pixel driving circuits of the first to fourth rows normally and not refreshing the pixel driving circuits of the fifth row is achieved.

Since the first gating module 21 and the second gating module 22 are introduced into the shift register, in the embodiments of the present disclosure, the first gating module 21 and the second gating module 22 in a same shift register can output different scanning signals (e.g., one includes a valid level signal and the other does not include a valid level signal), so that the pixel driving circuits with different refresh requirements can receive a correct scanning signal, which is beneficial to improving the display accuracy during regional refresh.

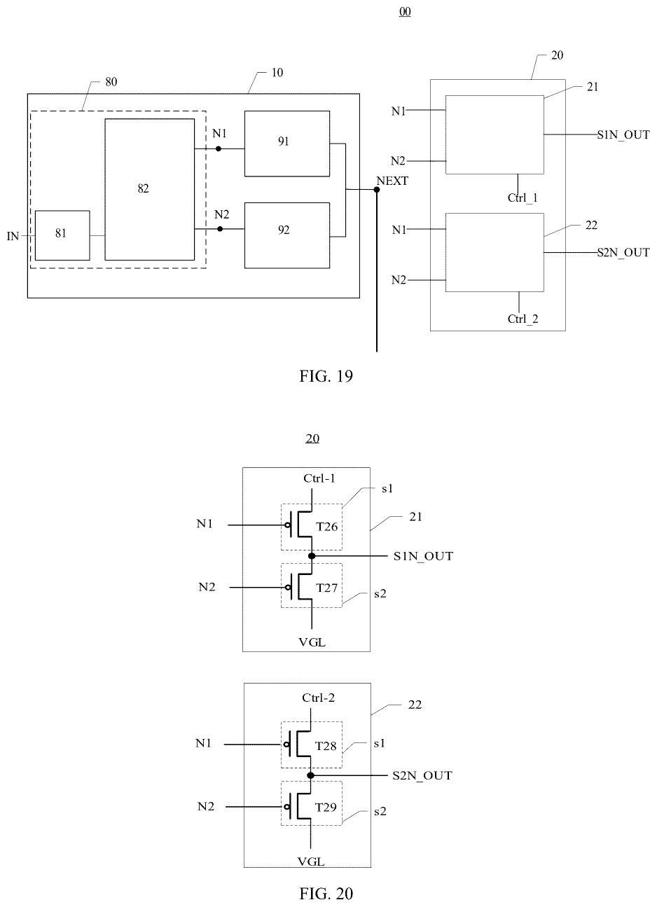

FIG. 19 illustrates another schematic structural diagram of a gate driving circuit in accordance with an embodiment of the present disclosure. In comparison with FIG. 12, in the same shift register 00, the first gating module 21 and the second gating module 22 are not connected to the stage transmission signal NEXT output by the stage transmission module 10 as shown in FIG. 19.

In some embodiments, the stage transmission module 10 includes a control unit 80, a first output component 91 and a second output component 92 electrically connected to the control unit 80. The first output component 91 and the control unit 80 are connected to the first node N1, and the second output component 92 and the control unit 80 are connected to the second node N2. The first output component 91 and the second output component 92 output the stage transmission signal NEXT according to the signal of the first node N1 and the signal of the second node N2. The gating module 20 is configured to output the scanning signal according to the frequency control signal Ctrl_1/Ctr_2, the signal of the first node N1 and the signal of the second node N2.

It should be noted that the specific structure, circuit and working principle of the stage transmission module 10 in this embodiment can refer to the embodiments shown in FIGS. 13 and 14, and the present disclosure will not repeat here. It can be seen from FIGS. 13 and 14, that in the Ta-Td stage, when the stage transmission signal NEXT is output at a high level, one of the first node N1 and the second node N2 is at a low level and the other is at a high level. The embodiments of the present disclosure are described by taking the level of the first node N1 at a low level and the level of the second node at a high level as an example.

FIG. 20 illustrates a schematic structural diagram of a gating module corresponding to the embodiment of FIG. 19. In combination with FIGS. 19 and 20, in some embodiments, the first gating module 21 and the second gating module 22 in the gating module 20 include a first output unit s1 and a second output unit s2, respectively. The control end of the first output unit s1 receives the signal of the first node N1, the input end receives the frequency control signal Ctrl_1/Ctrl_2, and the output end is connected to the output end S1N_OUT/S2N_OUT of the gating module. The control end of the second output unit s2 receives the signal of the second node N2, the input end receives a second level signal VGL, and the output end is connected to the output end S1N_OUT/S2N_OUT of the gating module. Optionally, the frequency control signal received by the first gating module 21 is the first frequency control signal Ctrl_1, and the frequency control signal received by the second gating module 22 is the second frequency control signal Ctrl_2.

In the illustrated embodiment, the first gating module 21 and the second gating module 22 are electrically connected to the first node N1 and the second node N2 in the stage transmission module 10, respectively, and also receive the frequency control signal Ctrl_1/Ctrl_2, respectively. The first gating module 21 and the second gating module 22 can output scanning signals according to the frequency control signal Ctrl_1/Ctrl_2, the signal of the first node N1, and the signal of the second node N2, respectively.

Referring to FIG. 20, exemplarily, the first output unit s1 in the first gating module 21 includes a transistor T26, the second output unit 32 includes a transistor T27, the first output unit s1 in the second gating module 22 includes a transistor T28, and the second output unit 32 includes a transistor T29. When the signal of the first node N1 controls the transistor T26 to turn on, the first frequency control signal Ctrl_1 will be output from the output end S1N_OUT of the first gating module 21 as a scanning signal. Similarly, when the signal of the first node N1 controls the transistor T28 to turn on, the second frequency control signal Ctrl_2 will be output from the output end S2N_OUT of the second gating module 22 as a scanning signal. In this way, in the scanning stage, when the gating module needs to output a valid level signal of the scanning signal, the frequency control signal including the valid level can be output as the scanning signal through the first output unit 31. When the gating module needs to output an invalid level signal of the scanning signal, the frequency control signal not including a valid level is also output as the scanning signal through the first output unit 31. By adjusting the frequency control signal, different output requirements of the gating module can be met.

When the first gating module 21 and the second gating module 22 are respectively embodied as the structure shown in FIG. 20, the first gating module 21 and the second gating module 22 respectively include two transistors, and the gates of the two transistors are respectively connected to the first node N1 and the second node N2 in the stage transmission module 10. The conduction of the transistors is controlled by the potentials of the first node N1 and the second node N2. At this time, the gating module can output a scanning signal according to the frequency control signal, the signals of the first node and the second node. In addition, in the present disclosure, the first gating module 21 and the second gating module 22 are respectively composed of two transistors, and the structure is relatively simple, which is conducive to simplifying the overall structure of the gate driving circuit and reducing the space occupied by the gate driving circuit in the display panel, so it is conducive to realizing the narrow frame design of the display panel.

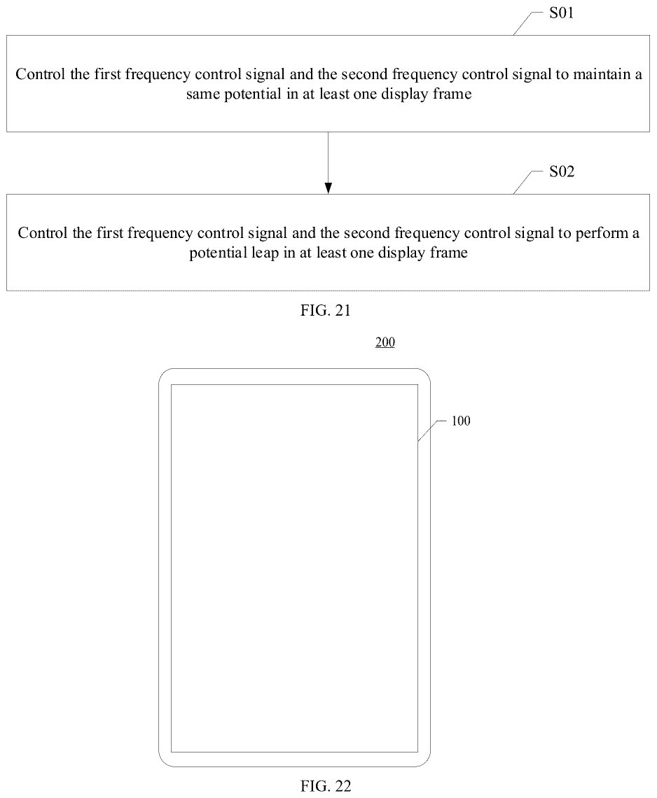

Based on similar inventive concepts, the present disclosure further provides a driving method for driving a display panel. FIG. 21 illustrates a flow chart of a driving method for driving a display panel in accordance with an embodiment of the present disclosure. The driving method for driving the display panel in the illustrated embodiment is used to drive a display panel in the disclosed embodiments. In conjunction with FIGS. 11 and 21 and FIGS. 16 to 18, the first gating module 21 receives a first frequency control signal Ctrl_1, and the second gating module 22 receives a second frequency control signal Ctrl_2. The driving method includes the following steps.
S01: Control the first frequency control signal and the second frequency control signal to maintain a same potential in at least one display frame.
S02: Control the first frequency control signal and the second frequency control signal to perform a potential leap in at least one display frame. A display frame includes a first stage T01 and a second stage T02. In the first stage T01, the first frequency control signal Ctrl_1 and the second frequency control signal Ctrl_2 maintain the same potential. In the second stage T02, the first frequency control signal Ctrl_1 and the second frequency control signal Ctrl_2 undergo a potential leap, and the potential leap timing of the first frequency control signal is earlier than the potential leap timing of the second frequency control signal.

It should be noted that there is no order of the two steps S01 and S02 mentioned in the method.

When the first frequency control signal and the second frequency control signal are controlled to maintain the same potential in a display frame, for example, the first frequency control signal and the second frequency control signal can both be low-level signals. Referring to FIG. 16, at this time, each shift register can output a valid level signal in the scanning signal, and each row of pixel driving circuits can be refreshed. In a display frame, when the first frequency control signal and the second frequency control signal are both high-level signals, for example, referring to FIG. 17, the scanning signals output by each shift register only include invalid level signals, and each row of pixel driving circuits will not be refreshed.

When the first frequency control signal and the second frequency control signal have a potential leap in a display frame, some pixel circuit rows can be controlled to be refreshed, while other pixel circuit rows are controlled not to be refreshed.

For example, referring to FIGS. 11 and 18, in the first stage T01, assuming that the first frequency control signal and the second frequency control signal are both low-level signals, the shift registers located in the first to third stages can output a scanning signal including a valid level signal to achieve the refresh of the pixel driving circuits in the first to fourth rows.

In the second stage T02, when the shift register of the third stage outputs a valid level signal in the stage transmission signal, the first frequency control signal Ctrl_1 first leaps from a low level to a high level, and the second frequency control signal Ctrl_2 is still a low-level signal. The second gating module 22 in the third-stage shift register can still output a scanning signal including a valid level signal to the pixel driving circuits in the third and fourth rows. While the first gating module 21 outputs a scanning signal including merely an invalid level signal to the pixel driving circuit in the fifth and sixth rows, and it does not reset the gates of the driving transistors in the pixel driving circuits in the fifth and sixth rows.

When the valid level signal in the output stage transmission signal of the fourth-stage shift register is transmitted, the second frequency control signal Ctrl_2 has leaped from a low-level signal to a high-level signal, and the first frequency control signal Ctrl_1 is maintained as a high-level signal. Thus, the first gating module 21 and the second gating module 22 of the fourth-stage shift register merely output the scanning signals including invalid level signals, and starting from the fifth and sixth rows of pixel driving circuits, the subsequent rows of pixel driving circuits all are not being refreshed. In this way, the regional refresh of the pixel driving circuits of the first to fourth rows but not the pixel driving circuits of the fifth row and subsequent rows can be achieved.

Since the first gating module 21 and the second gating module 22 are introduced into a shift register in the embodiments of the present disclosure, the first gating module 21 and the second gating module 22 in a same shift register can output different scanning signals. For example, one includes a valid level signal and the other does not, so that the pixel driving circuits with different refresh requirements can receive the correct scanning signal, which is beneficial to improving the display accuracy during regional refresh.

Based on similar inventive concepts, the present disclosure also provides a display device. FIG. 22 illustrates a schematic structural diagram of a display device 200 in accordance with an embodiment of the present disclosure. Referring to FIG. 22, the display device 200 includes a display panel 100 in any of the above embodiments. The display device 200 described in the embodiments of the present disclosure can be any electronic device with a display function, such as a touch screen, a mobile phone, a tablet computer, a laptop computer, an e-book, a television, etc. The display device 200 described in the embodiments of the present disclosure has the beneficial effects. The details can refer to the specific description of the display panel in the above embodiments, which will not be repeated here.

It can be understood that FIG. 22 merely illustrates one shape of the display device 200 by taking a rounded rectangular structure as an example. In some embodiments of the present disclosure, the display device 200 may also be circular, elliptical or any other feasible shape, which is not limited in the present disclosure.

In summary, the technical solutions provided by the embodiments of the present disclosure have the following advantages.

In a display panel, driving method and display device provided by the embodiments of the present disclosure, a same shift register can output two scanning signals through the first gating module and the second gating module respectively. Here, in at least some shift registers, the output end of the first gating module and the output end of the second gating module are respectively connected to the pixel driving circuits of different rows.

Assuming that in a same shift register, the first gating module is connected to the pixel driving circuits of an a-th row, and the second gating module is connected to the pixel driving circuits of a b-th row. When the refresh requirements for different display areas are different, for example, when the pixel driving circuits of the a-th row need to be refreshed, and the pixel driving circuits of the b-th row do not need to be refreshed. The first gating module can output a valid level signal of the scanning signal to the pixel driving circuits of the a-th row to refresh the pixel driving circuits of the a-th row, and the second gating module can output an invalid level signal of the scanning signal to the pixel driving circuits of the b-th row, without refreshing the pixel driving circuits of the b-th row. Thus, the pixel driving circuits with different refresh requirements can all receive the correct scanning signal, which is conducive to improving the display accuracy during a regional refresh.

It should be noted that, in the present disclosure, the terms such as “first” and “second” are merely used to distinguish one object or implementation from another object or implementation, and do not necessarily require or imply any such actual relationship or order between these objects or implementations. Moreover, the terms “include”, “comprise” or any other alternatives are intended to cover non-exclusive inclusion, so that a process, method, object or device including a series of factors includes not merely those factors, but also other factors not explicitly listed, or also includes factors inherent to such process, method, object or device. In the absence of further restrictions, the factors defined by the sentence “comprise a . . . ” do not exclude the existence of other identical factors in the process, method, article or device.

The forgoing description is merely some embodiments of the present disclosure, so that those skilled in the art can understand or implement the present disclosure. Various modifications to these embodiments will be apparent to those skilled in the art, and the general principles defined herein may be implemented in other embodiments without deviating from the spirit or scope of the present disclosure. Therefore, the present disclosure will not be limited to the embodiments described herein, but will conform to the widest scope consistent with the principles and novel features disclosed herein.

What is claimed is:

1. A display panel, comprising a gate driving circuit and a plurality of pixel driving circuits, wherein the gate driving circuit includes N-stage cascaded shift registers, and N≥2, wherein:
a shift register includes a stage transmission module and at least two gating modules connected to the stage transmission module, and the at least two gating modules include a first gating module and a second gating module;
the stage transmission module is configured to output a stage transmission signal, and a stage transmission signal of an i-th stage shift register is an input signal of a j-th stage shift register, wherein 1≤i≤N, 1≤j≤N, and i≠j; and
the first gating module and the second gating module are configured to at least receive a frequency control signal and output a scanning signal through an output end of the first gating module and an output end of the second gating module, and in at least some of the shift registers, the output end of the first gating module and the output end of the second gating module are respectively connected to pixel driving circuits of different rows.

2. The display panel according to claim 1, wherein, in at least one display frame, the first gating module and the second gating module in at least one shift register are configured to receive different frequency control signals respectively.

3. The display panel according to claim 2, wherein, in the at least one display frame, in the frequency control signals received by the first gating module and the second gating module in the at least one shift register, one signal is a high-level signal and another signal is a low-level signal.

4. The display panel according to claim 2, wherein, in the at least one display frame and in the at least one shift register, a scanning signal output by the first gating module to corresponding pixel driving circuits includes a valid level signal, and a scanning signal output by the second gating module to corresponding pixel driving circuits does not include the valid level signal; or the scanning signal output by the first gating module to the corresponding pixel driving circuits does not include the valid level signal, and the scanning signal output by the second gating module to the corresponding pixel driving circuits includes the valid level signal.

5. The display panel according to claim 1, wherein, in at least one display frame, the first gating module and the second gating module in the shift register are configured to receive a same frequency control signal.

6. The display panel according to claim 5, wherein, in the at least one display frame, and in at least one of the shift registers, scanning signals output by the first gating module and the second gating module to corresponding pixel driving circuits both include a valid level signal or neither include the valid level signal.

7. The display panel according to claim 1, wherein:
a pixel driving circuit includes a first control signal terminal and a second control signal terminal, wherein the first control signal terminal and the second control signal terminal are used to receive different scanning signals output by the shift register; and
in s-th and p-th rows of pixel driving circuits, the second control signal terminal is connected to an output terminal of the second gating module in an m-th stage shift register, and the first control signal terminal is connected to an output terminal of the first gating module in an n-th stage shift register, wherein s≥1, p≥1, s≠p, and m>n≥1.

8. The display panel according to claim 7, wherein in at least one display frame, scanning signals received by the first control signal terminal and the second control signal terminal in a same row of pixel driving circuits both include a valid level signal; or the scanning signals received by the first control signal terminal and the second control signal terminal in the same row of pixel driving circuits neither include the valid level signal.

9. The display panel according to claim 7, wherein p=s+1 and m−n=1.

10. The display panel according to claim 9, wherein, in (p+1)-th row and (p+2)-th row of pixel driving circuits, the second control signal terminal is connected to an output terminal of the second gating module in an (m+1)-th stage shift register, and the first control signal terminal is connected to an output terminal of the first gating module in an m-th stage of the shift register.

11. The display panel according to claim 1, wherein:
the display panel includes C circuit groups, and one circuit group includes at least one row of pixel driving circuits, wherein C≥1 and N≥C+1;
a pixel driving circuit includes a first control signal terminal and a second control signal terminal, and the first control signal terminal and the second control signal terminal are used to receive scanning signals output by different shift registers; and
in one circuit group, first control signal terminals of pixel driving circuits are connected to an output terminal of the first gating module in one shift register, and second control signal terminals of the pixel driving circuits are connected to an output terminal of the second gating module in another shift register.

12. The display panel according to claim 11, wherein:
in the gate driving circuit, an output end of the second gating module in at least a first-stage shift register is floating or connected to a first signal line, and the first signal line is not connected to the pixel driving circuits; and/or,
an output end of the first gating module in at least a last stage shift register is floating or connected to a second signal line, and the second signal line is not connected to the pixel driving circuits.

13. The display panel according to claim 1, wherein, in the shift register, the first gating module and the second gating module have a same circuit structure.

14. The display panel according to claim 1, wherein:
the display panel includes two groups of gate driving circuits, and a pixel driving circuit includes a first control signal terminal and a second control signal terminal; and
first control signal terminals of pixel driving circuits in a same row are electrically connected to same stage shift registers in the two groups of gate driving circuits, and second control signal terminals of the pixel driving circuits in the same row are electrically connected to the same stage shift registers in the two groups of gate driving circuits; and two shift registers connected to the pixel driving circuits in the same row are respectively located on both sides of the row of pixel driving circuits.

15. The display panel according to claim 1, wherein:
a pixel driving circuit includes a first control signal terminal and a second control signal terminal, wherein the first control signal terminal and the second control signal terminal are used to receive different scanning signals output by the shift register; and
the pixel driving circuit includes a driving transistor, a reset module and a threshold compensation module, wherein:
the reset module is connected between a reset signal terminal and a gate of the driving transistor, and the threshold compensation module is connected between the gate of the driving transistor and a first electrode of the driving transistor; a control terminal of the reset module is connected to the first control signal terminal, and a control terminal of the threshold compensation module is connected to the second control signal terminal, and
in one pixel driving circuit, the first control signal terminal receives a scanning signal output by the first gating module of one shift register, and the second control signal terminal receives a scanning signal output by the second gating module of another shift register.

16. The display panel according to claim 1, wherein the stage transmission module includes a control unit and a first output component and a second output component electrically connected to the control unit, wherein:
the first output component and the control unit are connected to a first node, and the second output component and the control unit are connected to a second node, the first output component and the second output component output the stage transmission signal according to a signal of the first node and a signal of the second node; and
a gating module is configured to output the scanning signal according to at least the frequency control signal, the signal of the first node, and the signal of the second node.

17. The display panel according to claim 16, wherein the gating module is configured to output the scanning signal further according to the stage transmission signal.

18. The display panel according to claim 17, wherein:
the gating module includes a first output unit, a second output unit, an isolation protection unit, and an output control unit, wherein:
a control end of the isolation protection unit receives the stage transmission signal, an input end of the isolation protection unit receives the frequency control signal, and an output end of the isolation protection unit is connected to a control end of the output control unit,
an input end of the output control unit receives the signal of the first node, and an output end of the output control unit is connected to a control end of the first output unit,
an input end of the first output unit receives a first level signal, and an output end of the first output unit is connected to an output end of the gating module, and
a control end of the second output unit receives the signal of the second node, an input end of the second output unit receives a second level signal, and an output end of the second output unit is connected to the output end of the gating module.

19. The display panel according to claim 16, wherein the gating module includes a first output unit and a second output unit, wherein:
a control end of the first output unit receives the signal of the first node, an input end of the first output unit receives the frequency control signal, and an output end of the first output unit is connected to an output end of the gating module; and
a control end of the second output unit receives the signal of the second node, an input end of the second output unit receives a second level signal, and an output end of the second output unit is connected to the output end of the gating module.

20. A driving method for driving a display panel, the display panel including a gate driving circuit and a plurality of pixel driving circuits, wherein the gate driving circuit includes N-stage cascaded shift registers, and N≥2, a shift register includes a stage transmission module and at least two gating modules connected to the stage transmission module, and the at least two gating modules include a first gating module and a second gating module; the stage transmission module is configured to output a stage transmission signal, and a stage transmission signal of an i-th stage shift register is an input signal of a j-th stage shift register, wherein 1≤i≤N, 1≤j≤N, and i≠j; and the first gating module and the second gating module are configured to at least receive a frequency control signal and output a scanning signal through an output end of the first gating module and an output end of the second gating module, and in at least some of the shift registers, the output end of the first gating module and the output end of the second gating module are respectively connected to pixel driving circuits of different rows, and wherein the first gating module receives a first frequency control signal and the second gating module receives a second frequency control signal, and the method comprising:
controlling the first frequency control signal and the second frequency control signal to maintain a same potential in at least one display frame; and
controlling the first frequency control signal and the second frequency control signal to undergo a potential leap in at least one display frame, wherein:
a display frame includes a first stage and a second stage, and
in the first stage, the first frequency control signal and the second frequency control signal maintain the same potential, in the second stage, the first frequency control signal and the second frequency control signal undergo the potential leap, and a potential leap timing of the first frequency control signal is earlier than a potential leap timing of the second frequency control signal.
